(19) United States
(12) Patent Application Publication
(10) Pub. No.: US 2026/0040551 A1
(43) Pub. Date: Feb. 5, 2026

(54) MICROELECTRONIC DEVICES WITH WORD LINE CONTACTS EXTENDING INTO A TIERED STACK HAVING PARTIALLY CONDUCTIVE LEVELS, AND RELATED METHODS

(71) Applicant: Micron Technology, Inc., Boise, ID (US)

(72) Inventors: Anna Maria Conti, Milano (IT); Giovanni Mazzone, Villasanta (IT); Paolo Tessariol, Arcore (IT); Sidhartha Gupta, Boise, ID (US)

(21) Appl. No.: 19/255,941

(22) Filed: Jun. 30, 2025

Related U.S. Application Data
(60) Provisional application No. 63/677,332, filed on Jul. 30, 2024.

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A microelectronic device includes a stack divided into blocks and having a vertically repeated sequence of tiers. The tiers include insulative level(s) and other level(s). The other levels are partially conductive and partially non-conductive. In a first area of the stack, an array of pillars extends substantially vertically through a height of the stack, and the tiers include the insulative level(s) and conductive portion(s) in the other level(s). In a second area of the stack, conductive contacts extend to various depths, and the tiers include the insulative level(s) and both conductive and non-conductive portion(s) in the other level(s). In methods of forming a microelectronic device, a precursor stack is formed including insulative structures and partially-sacrificial structures. In an area in which conductive contacts are formed to various levels of the stack, portions of the partially-sacrificial structures are removed and replaced with conductive structures, leaving remnants of the partially-sacrificial structures.

### CROSS-REFERENCE TO RELATED APPLICATION

This application claims the benefit, under 35 U.S.C. § 119(e), of U.S. Provisional Patent Application Ser. No. 63/677,332, filed Jul. 30, 2024, the disclosure of which is hereby incorporated in its entirety herein by this reference.

### TECHNICAL FIELD

The disclosure, in various embodiments, relates generally to the field of microelectronic device design and fabrication. More specifically, the disclosure relates to methods of forming microelectronic devices and to related microelectronic devices and electronic systems.

### BACKGROUND

Memory devices provide data storage for electronic systems. A Flash memory device is one of various memory device types and has numerous uses in modern computers and other electrical devices. A conventional Flash memory device may include a memory array that has a large number of charge storage devices (e.g., memory cells, such as non-volatile memory cells) arranged in rows and columns. In a NAND architecture type of Flash memory, memory cells arranged in a column are coupled in series, and a first memory cell of the column is coupled to a data line (e.g., a bit line). In a “three-dimensional NAND” memory device (which may also be referred to herein as a “3D NAND” memory device), a type of vertical memory device, not only are the memory cells arranged in row and column fashion in a horizontal array, but tiers of the horizontal arrays are stacked over one another (e.g., as vertical strings of memory cells) to provide a “three-dimensional array” of the memory cells. The stack of tiers vertically repeat tiers that include at least one electrically conductive material and at least one electrically insulating (e.g., dielectric) material. The conductive materials function as control gates for, e.g., word lines (e.g., access lines) of the memory cells. In so-called “array” areas of the devices, vertical structures (e.g., pillars comprising channel structures and tunneling structures) extend along the vertical string of memory cells. A drain end of a string may be adjacent a top and/or bottom of the vertical structure (e.g., pillar), and a source end of the string may be adjacent some other portion of the pillar, such as the other of the top and bottom of the pillar or a middle portion of the pillar. The drain end is operably connected to a bit line, while the source end or portion is operably connected to a source structure (e.g., a source plate, a source line). A 3D NAND memory device also includes electrical connections between, e.g., word lines (e.g., access lines) and other conductive structures of the device so that the memory cells of the vertical strings can be selected for writing, reading, and erasing operations.

Some 3D NAND memory devices include so-called “staircase” structures arranged in so-called “stadiums” and having “steps” (or otherwise known as “stairs”) at edges (e.g., ends) of the tiers of the stack. These stadiums and their stepped staircases may be formed in one or more areas of the device, which may each be referred to herein as a “staircase area.” The steps of the staircased stadiums may be formed by patterning the stack to provided terraced tiers, with each terrace defining one or more of the steps. The steps provide contact regions to conductive structures of the device (e.g., contact regions to conductive materials/structures, such as to access/world lines of the tiered stack). Contact structures (e.g., so-called “word line contacts,” also referred to herein as “WL contacts”) extend through stadium openings to physically contact the conductive structures of the steps so as to provide electrical access to the conductive structures (e.g., access/word lines).

Some other 3D NAND memory devices omit the terraced patterning of the tiered stack. These 3D NAND memory devices may be free of stadiums and free of staircases of ascending or descending steps/stairs in the area in which the WL contacts are to be formed. This area—described above as a “staircase area” of devices with stadiums and staircases—is referred to herein as a “WL-contact area” for device(s) lacking staircases and stadiums. In the WL-contact area, WL contacts extend through discrete contact openings defined in the materials of the stack. The WL contacts extend to various depths (e.g., levels, elevations) of the stack to come into physical contact with target word lines (e.g., access lines). That is, the WL contacts extend to conductive structures at various target levels of the tiered stack.

Whether extending through stadium openings or through discrete contact openings, the WL contacts may be in electrical communication (e.g., via conductive routing lines) to additional contact structures (so-called “through-stack vias”), which may communicate through the tiered stack to additional routing lines, which may be in the source/drain region(s). The additional routing lines may electrically communicate to string drivers that drive the word line (e.g., access line) voltages to write to or read from the memory cells controlled via the word lines (e.g., access lines).

A continued goal in the microelectronic device fabrication industry is to design device features that may be reliably and consistently formed. Achieving this goal tends to be challenging. For example, conventional methods for forming 3D NAND memory devices include forming an initial tiered stack of insulative and sacrificial materials and then wholly replacing the sacrificial material(s) with conductive material(s) to form the conductive structures of a stack, with the conductive structures vertically alternating with insulative structures. This replacement process generally involves substantially wholly removing the sacrificial material(s) from the device areas where the pillars and the WL contacts are to be formed (e.g., from the pillar array area(s) and from the staircase area(s) or the WL-contact area(s)). Removing the sacrificial material(s) leaves the insulative material(s) with less structural support, which may lead to the insulative material(s) deforming (e.g., sagging, collapsing). Deformed insulative material(s) may then, in turn, inhibit accurate formation of the conductive material(s) in the spaces previously occupied by the sacrificial material(s). Efforts have been made to include through-stack support structures to maintain some structural support to the insulative material(s) upon removal of the sacrificial material(s). However, these support structures occupy some footprint of the device, which adds to the challenges of device scaling and minimizing horizontal footprint. Accordingly, memory device design and fabrication continues to present challenges.

### BRIEF DESCRIPTION OF THE DRAWINGS

FIG. 1 through FIG. 12B are partial cross-sectional views illustrating various stages of method(s) of forming a microelectronic device, such as a microelectronic device including the microelectronic device structure(s) of FIG. 12A and FIG. 12B, in accordance with embodiments of the disclosure.

FIG. 13A through FIG. 17B are partial cross-sectional views illustrating various stages of method(s) of forming a microelectronic device, such as a microelectronic device including the microelectronic device structure(s) of FIG. 17A and FIG. 17B, in accordance with embodiments of the disclosure, wherein the method(s) may also include the stages illustrated in FIG. 1 through FIG. 5B, the illustrated stages of which may precede the stage(s) illustrated in FIG. 13A and FIG. 13B.

FIG. 18A and FIG. 18B are partial cross-sectional views of microelectronic device structure(s) of microelectronic device(s), in accordance with embodiments of the disclosure.

FIG. 19A and FIG. 19B are partial cross-sectional views of microelectronic device structure(s) of microelectronic device(s), in accordance with embodiments of the disclosure.

FIG. 20A and FIG. 20B are partial cross-sectional views of microelectronic device structure(s) of microelectronic device(s), in accordance with embodiments of the disclosure.

FIG. 21A through FIG. 24B are partial cross-sectional views illustrating various stages of method(s) of forming a microelectronic device, such as a microelectronic device including the microelectronic device structure(s) of FIG. 24A and FIG. 24B, in accordance with embodiments of the disclosure, wherein the method(s) may also include the stage illustrated in FIG. 1, which illustrated stage may precede the stage(s) illustrated in FIG. 21A and FIG. 21B.

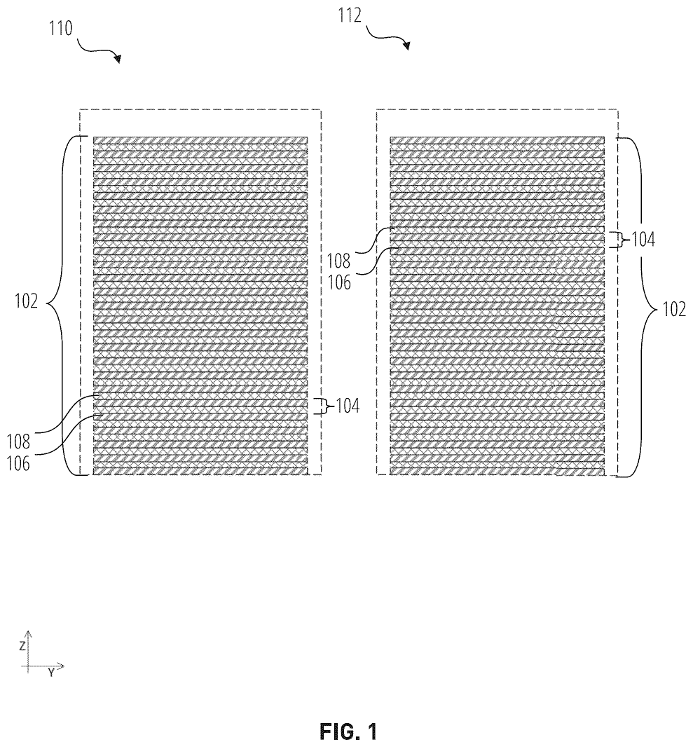

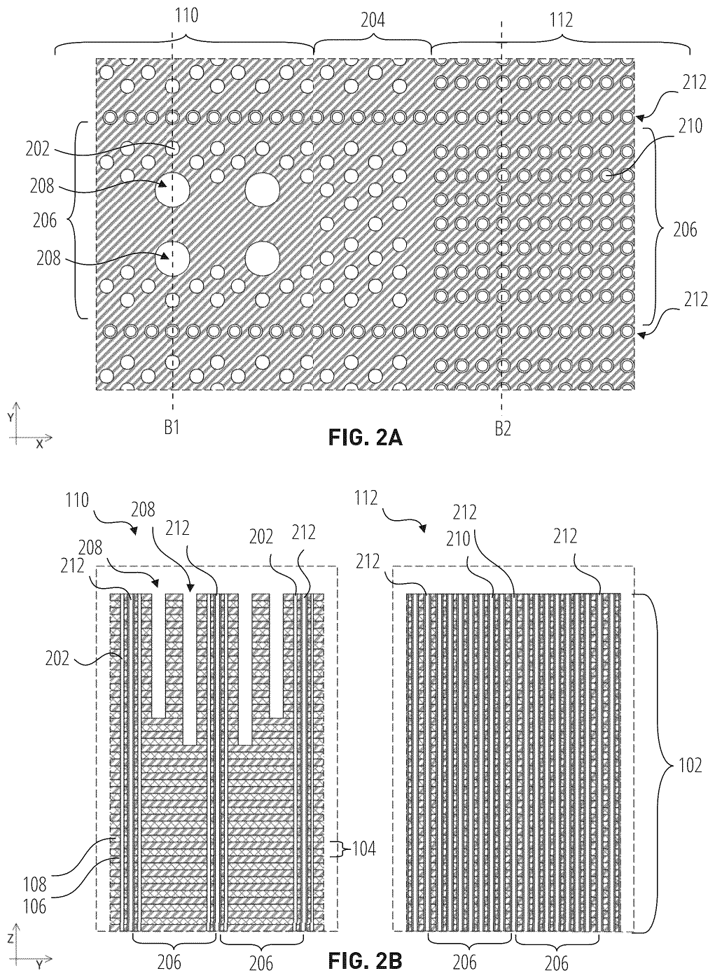

Within FIG. 2A to FIG. 24B, drawings sharing a same figure number (i.e., FIG. “2”A and FIG. “2”B) may illustrate a same process stage and/or may illustrate different portions of a same microelectronic structure and device. Drawings designated with letter “A” are top plan illustrations. Drawings designated with letter “B” are elevational views corresponding to section lines B1 and B2 of the corresponding “A” drawing. FIG. 1 is also an elevational view. Section line B1 (in “A” drawings) and the left-side of the elevational-view drawings correspond to a WL-contact area of the device (e.g., an area of the device that includes word line (e.g., “WL”) (e.g., access line) contacts). Section line B2 (in “A” drawings) and the right-side of the elevational-view drawings correspond to an array area of the device (e.g., an area of the device that includes an array of pillars (e.g., including channel structures and tunnel structures) providing vertical strings of memory cells).

FIG. 25 is a block diagram of an electronic system having microelectronic device(s) that include at least one microelectronic device structure of embodiments of the disclosure.

### DETAILED DESCRIPTION

Structures (e.g., microelectronic device structures), apparatuses (e.g., microelectronic devices, e.g., memory device(s), such as 3D NAND Flash memory device(s)), and systems (e.g., electronic systems), according to embodiments of the disclosure, include a stack having a vertically repeated pattern of tiers of insulative structures and other structures. The levels of the stack occupied by other structures are conductive in some areas and non-conductive (e.g., insulative) in other areas of the device. Thus, in at least one area of the device, the stack includes a vertically repeated pattern of tiers that are substantially free of conductive structures, such as a vertically repeated pattern of tiers of insulative structures and additional insulative structures. In at least one other area of the device, the stack includes a vertically repeated pattern of tiers that include conductive structures, such as a vertically repeated pattern of tiers of insulative structures and conductive structures. The microelectronic devices formed through the methods of the disclosure include conductive contacts (e.g., word line (WL) contacts) extending through areas of the stack that may be otherwise unpatterned. These conductive, WL contacts are through-stack contacts that land on or in target levels (e.g., elevations) of the tiered stack. In the landing area(s) (e.g., contact regions), the target levels include the conductive structures, and these conductive structures are adjacent non-conductive (e.g., insulative, e.g., nitride) structures that occupy other areas of the respective target levels. The non-conductive structures of the otherwise-conductive levels may be formed from partially-sacrificial structures (referred to herein as “parsac” structures in the interest of brevity). During fabrication, the presence of the parsac structures provides structural support for insulative structures of the tiered stack, such as during partial removal of the parsac structures and during formation of the conductive structures in replacement of the removed portions of the parsac structures. The inclusion of supportive parsac structures may not necessitate increasing horizontal footprint of the device. The stack areas retaining portions of the parsac structures may be substantially free from so-called “supports.” Therefore, these areas may occupy relatively lesser horizontal footprint of the device than if supports were included. Supports may be included in other areas of the device, such as areas adjacent the WL contacts and such as in areas in which the tiered stack includes conductive structures. With the additional support of the parsac structures, the resulting microelectronic device(s) may be formed with reliability and accuracy (e.g., with lessened risk of collapse or sagging of the insulative structure levels in the stack) and with minimal horizontal footprint occupied by supports.

In light of the detailed description provided below, it will be readily apparent to one of ordinary skill in the art that the methods and structures described herein may be used in various devices and systems. The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and they are not meant to be actual views of any particular material, component, structure, device, or system. Variations from the shapes depicted in the drawings (e.g., as a result of manufacturing techniques and/or tolerances) are to be expected. Thus, embodiments described herein are not to be construed as being limited to the particular shapes or regions as illustrated, but include deviations in shapes that result, e.g., from manufacturing. For example, a region illustrated or described as box-shaped may alternatively have rough and/or nonlinear features, and a region illustrated or described as round may alternatively include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes a microelectronic device exhibiting, but not limited to, memory functionality.

As used herein, the term “through-stack”—when referring to a structure, such as a conductive contact (e.g., word line contact, also referred to herein as a “WL contact”)—means and refers to the structure extending through an otherwise nonpatterned area of the stack. Thus, a “through-stack” WL contact may be formed within a discrete opening defined in the stack such that the “through-stack” WL contact is physically separated from neighboring WL contacts by substantially nonpatterned area(s) of the stack.

As used herein, the term “sacrificial,” when used in reference to a material or structure, means and includes a material or structure that is formed during a fabrication process but which is substantially removed (e.g., wholly removed) prior to completion of the fabrication process.

As used herein, the terms “partially-sacrificial” and “parsac” (as abbreviated for the sake of brevity), when used in reference to a material or structure, means and includes a material or structure that is formed during a fabrication process but which is partially, but not wholly, removed prior to completion of the fabrication process. A partially-sacrificial (parsac) structure may remain in a final device (e.g., a final structure of a device) in a manner that it maintains at least one original dimension (e.g., an original vertical thickness) in the areas in which the partially-sacrificial (parsac) structure remains. A “partially-sacrificial” material or structure may be wholly or substantially removed from some area(s) of the device (e.g., an array area) and still constitute a “partially-sacrificial” (parsac) material or structure if at least one area of the device (e.g., a WL-contact area) continues to include portions of the “partially-sacrificial” material/structure.

As used herein, the term “high-aspect-ratio” means and refers to a height-to-width (e.g., a ratio of a maximum vertical height to a maximum horizontal width/length) of greater than about 10:1 (e.g., greater than about 20:1, greater than 30:1, greater than about 40:1, greater than about 50:1, greater than about 60:1, greater than about 70:1, greater than about 80:1, greater than about 90:1, greater than about 100:1).

As used herein, a feature referred to with the adjective “source/drain” means and refers to the feature being configured for association with either or both the source region and the drain region of the device that includes the “source/drain” feature. A “source region” may be otherwise configured as a “drain region” and vice versa without departing from the scope of the disclosure.

As used herein, the terms “opening,” “trench,” and “slit” mean and include a volume extending through or into at least one structure or at least one material, leaving a gap in that at least one structure or at least one material; or a volume extending between structures and/or materials, leaving a gap between the structures and/or materials. Unless otherwise described, an “opening,” “trench,” and/or “slit” is not necessarily empty of material. That is, an “opening,” “trench,” or “slit” is not necessarily void space. An “opening,” “trench,” or “slit” formed in or between structures or materials may comprise structure(s) or material(s) other than that in or between which the “opening,” “trench,” or “slit” is formed. And, structure(s) or material(s) “exposed” within an opening, trench, or slit is/are not necessarily in contact with an atmosphere or non-solid environment. Structure(s) or material(s) “exposed” within an opening, trench, or slit may be adjacent or in contact with other structure(s) or material(s) that is/are disposed within the opening, trench, or slit.

As used herein, the terms “trench” and “slit” mean and include an elongate opening, while the terms “opening,” “recess,” and “void” may include one or more of an elongate opening, an elongate recess, an elongate void, a non-elongate opening, a non-elongate recess, or a non-elongate void.

As used herein, the term “elongate” means and includes a geometric shape including a dimension (e.g., a width, as defined below) in a first horizontal direction (e.g., a lateral direction, as defined below) that is substantially greater (e.g., at least ten-times greater) than an additional dimension (e.g., a length, as defined below) in a second horizontal direction (e.g., a longitudinal direction, as defined below) orthogonal to the first horizontal direction, or vice versa.

As used herein, the term “discrete” means and includes a geometric shape that is not elongate. A “discrete” structure or opening may have a dimension in a first horizontal direction that is no greater than about ten-times (e.g., up to about five-times, e.g., up to about two-times, e.g., about the same as) a dimension in a second horizontal direction orthogonal to the first horizontal direction.

As used herein, the terms “substrate,” “base structure,” and “base region” mean and include a base material, structure, region, or other construction upon which components, such as tiered stacks and structures therein, are formed. The substrate, base structure, or base region may be or include a semiconductor substrate, a base semiconductor material on a supporting structure, a metal electrode, or a semiconductor substrate having one or more materials, structures, or regions formed thereon. The substrate, base structure, or base region may be or include a “semiconductor,” “semiconductive,” and/or “semiconducting” material, such as one or more of a conventional silicon substrate or other bulk substrate including a semiconductive material. As used herein, the term “bulk substrate” means and includes not only silicon wafers, but also silicon-on-insulator (“SOI”) substrates, such as silicon-on-sapphire (“SOS”) substrates or silicon-on-glass (“SOG”) substrates, epitaxial layers of silicon on a base semiconductor foundation, or other “semiconductor,” “semiconductive,” “semiconducting,” and/or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. Furthermore, when reference is made to a “substrate,” “base structure,” or “base region” in the following description, previous process stages may have been utilized to form materials, structures, or junctions in the substrate, base structure, base region, or other foundation.

As used herein, the terms “insulative” and “insulating,” when used in reference to a material, region, or structure, means and includes a material, region, or structure that is electrically insulative or electrically insulating. An “insulative” or “insulating” material, region, or structure may be formed of and include one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiONₓN_{y})), at least one dielectric carboxynitride material (e.g., a silicon carboxynitride (SiOₓC_{z}N_{y})), and/or air. In addition, an “insulative” or “insulating” structure means and includes a structure formed of and including “insulative” or “insulating” material. In some embodiments, an “insulative” or “insulating” structure, region, or material is free or substantially free of “conductive,” “conducting,” “semiconductor,” “semiconductive,” and/or “semiconducting” material(s).

As used herein, the terms “conductive” and “conducting,” when used in reference to a material, region, or structure, mean and include a material, region, or structure that is electrically conductive or electrically conducting, unless otherwise specified (e.g., as “thermally conductive” or “thermally conducting”). A “conductive” or “conducting” material, region, or structure may be formed of and include one or more metals or metal-containing compositions. The one or more metals or metal-containing compositions may be in the form of a single homogeneous material region, in the form of multiple material regions (e.g., as one material region at least partially lined by a second material region (e.g., liner)). The metals may include one or more of tungsten (W), titanium (Ti), nickel (Ni), platinum (Pt), rhodium (Rh), ruthenium (Ru), iridium (Ir), aluminum (Al), copper (Cu), molybdenum (Mo), silver (Ag), and/or gold (Au). Metal-containing compositions may include one or more alloys, nitrides, silicides, carbides, and/or oxides of and including any of the foregoing metals, such as a material including one or more of titanium nitride (TiN), tantalum nitride (TaN), tungsten nitride (WN), titanium aluminum nitride (TiAlN), iridium oxide (IrOₓ), ruthenium oxide (RuOₓ), and/or alloys thereof. In some embodiments, a “conductive” or “conducting” material, region, or structure may be formed of and include one or more conductively-doped semiconductor material(s) (e.g., conductively-doped silicon, conductively-doped germanium, conductively-doped silicon germanium) and/or polysilicon. In some embodiments, a “conductive” or “conducting” material, region, or structure is free or substantially free of “insulative,” “insulating,” “semiconductor,” “semiconductive,” and/or “semiconducting” material(s).

As used herein, the terms “semiconductor” and “semiconductive,” when used in reference to a material, region, or structure, mean and include a material, region, or structure having an electrical conductivity between those of insulative materials and conductive materials. For example, a semiconductor material may have an electrical conductivity of between about 10⁻⁸ Siemens per centimeter (S/cm) and about 10+S/cm (10⁶ S/m) at room temperature. Examples of semiconductor materials include elements found in column IV of the periodic table of elements, such as silicon (Si), germanium (Ge), and carbon (C). Other examples of semiconductor materials include compound semiconductor materials, such as binary compound semiconductor materials (e.g., gallium arsenide (GaAs)), ternary compound semiconductor materials (e.g., AlₓGa₁₋ₓAs), and quarternary compound semiconductor materials (e.g., GaₓIn₁₋ₓAs_{y}P_{1-y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials, such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and/or “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and/or “z” atoms of an additional element (if any), respectively, for every one atom of another element (e.g., Si, Al, Hf, Nb, Ti). As the formulae are representative of relative atomic ratios and not strict chemical structure, an insulative material or insulative structure may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “precursor,” when referring to a material, region, or structure, means and refers to a material, region, or structure to be transformed into a resulting material, region, or structure. For example, and without limitation, a “precursor stack” may refer to a stack structure that is to be altered in its composition for formation of a final stack.

As used herein, the term “horizontal” means and includes a direction that is parallel to a primary surface of the substrate on which the referenced material, region, or structure is located. The “width” and “length” of a respective material, region, or structure may be defined as dimensions in a horizontal plane. With reference to the figures, the “horizontal” direction may be perpendicular to an indicated “Z” axis, may be parallel to an indicated “X” axis, and may be parallel to an indicated “Y” axis.

As used herein, the term “lateral” means and includes a direction in a horizontal plane parallel to a primary surface of the substrate on which a referenced material, region, or structure is located and substantially perpendicular to a “longitudinal” direction. The “width” of a respective material, region, or structure may be defined as a dimension in the lateral direction of the horizontal plane. With reference to the figures, the “lateral” direction may be parallel to an indicated “X” axis, may be perpendicular to an indicated “Y” axis, and may be perpendicular to an indicated “Z” axis.

As used herein, the term “longitudinal” means and includes a direction in a horizontal plane parallel to a primary surface of the substrate on which a referenced material, region, or structure is located, and substantially perpendicular to a “lateral” direction. The “length” of a respective material, region, or structure may be defined as a dimension in the longitudinal direction of the horizontal plane. With reference to the figures, the “longitudinal” direction may be parallel to an indicated “Y” axis, may be perpendicular to an indicated “X” axis, and may be perpendicular to an indicated “Z” axis.

As used herein, the term “vertical” means and includes a direction that is perpendicular to a primary surface of the substrate on which a referenced material, region, or structure is located. The “height” of a respective material, region, or structure may be defined as a dimension in a vertical plane. With reference to the figures, the “vertical” direction may be parallel to an indicated “Z” axis, may be perpendicular to an indicated “X” axis, and may be perpendicular to an indicated “Y” axis.

As used herein, the term “width” means and includes a dimension, along an indicated “X” axis in a horizontal plane (e.g., at a certain elevation, if identified), defining a maximum distance, along such “X” axis in the horizontal plane, of the whole of the material, region, or structure in question or of a concerned portion of the material, region, or structure in question. For example, a “width” of a level of a stack—whether such level is defined substantially by insulative structure(s) or whether such level is defined by conductive structure(s) in some portion(s) and non-conductive structure(s) in other portion(s)—may be a maximum X-axis dimension from one lateral end of the level to an opposite lateral end of the level.

As used herein, the term “length” means and includes a dimension, along an indicated “Y” axis in a horizontal plane (e.g., at a certain elevation, if identified), defining a maximum distance, along such “Y” axis in the horizontal plane, of the material, region, or structure in question or of a concerned portion of the material, region, or structure in question. For example, a “length” of a block may be a maximum Y-axis dimension from one block-defining opening (e.g., slit or discrete opening) to another block-defining opening (e.g., slit or discrete opening).

As used herein, the terms “thickness” or “thinness” are spatially relative terms that mean and include a dimension in a straight-line direction that is normal to the closest surface of an immediately adjacent material, region, or structure that is of a different composition or that is otherwise distinguishable from the material, region, or structure whose thickness, thinness, or height is discussed.

As used herein, the term “between” is a spatially relative term used to describe the relative disposition of one material, region, or structure relative to at least two other materials or structures. The term “between” may encompass both a disposition of one material, region, or structure directly adjacent the other materials or structures and a disposition of one material, region, or structure indirectly adjacent to the other materials or structures.

As used herein, the term “proximate” is a spatially relative term used to describe disposition of one material, region, or structure near to another material, region, or structure. The term “proximate” includes dispositions of indirectly adjacent to, directly adjacent to, and internal to.

As used herein, features (e.g., regions, materials, openings, structures, assemblies, devices) described as “neighboring” one another mean and include features of the disclosed identity (or identities) that are located most proximate (e.g., closest to) one another. One or more additional features (e.g., additional regions, additional materials, additional structures, additional openings, additional assemblies, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with the “neighboring” features is positioned between the “neighboring” features. For example, a structure of material X “neighboring” a structure of material Y is the first material X structure, e.g., of multiple material X structures, that is nearest the particular structure of material Y. Thus, for example, features described as “vertically neighboring” one another mean and include features of the disclosed identity (or identities) that are located most vertically proximate (e.g., vertically closest to) one another. Moreover, features described as “horizontally neighboring” one another mean and include features of the disclosed identity (or identities) that are located most horizontally proximate (e.g., horizontally closest to) one another.

As used herein, the term “consistent”—when referring to a parameter, property, or condition of one structure, material, feature, or portion thereof in comparison to the parameter, property, or condition of another such structure, material, feature, or portion of such same aforementioned structure, material, or feature—is a relative term that means and includes the parameter, property, or condition of the two such structures, materials, features, or portions being equal, substantially equal, or about equal, at least in terms of respective dispositions of such structures, materials, features, or portions. For example, two structures having “consistent” heights as one another may each define a same, substantially same, or about the same height, from a lower surface to an upper surface of each respective such structure, despite the two structures being at different elevations (e.g., levels) of a larger structure.

As used herein, the terms “about” and “approximately,” when either is used in reference to a numerical value for a particular parameter, are inclusive of the numerical value and a degree of variance from the numerical value that one of ordinary skill in the art would understand is within acceptable tolerances for the particular parameter. For example, “about” or “approximately,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0 percent met, at least 95.0 percent met, at least 99.0 percent met, or even at least 99.9 percent met.

As used herein, the terms “on” or “over,” when referring to an element as being “on” or “over” another element, are spatially relative terms that mean and include the element being directly on top of, adjacent to (e.g., laterally adjacent to, horizontally adjacent to, longitudinally adjacent to, vertically adjacent to), underneath, or in direct contact with the other element. It also includes the element being indirectly on top of, adjacent to (e.g., laterally adjacent to, horizontally adjacent to, longitudinally adjacent to, vertically adjacent to), underneath, or near the other element, with other elements present therebetween. In contrast, when an element is referred to as being “directly on” or “directly adjacent to” another element, there are no intervening elements present.

As used herein, other spatially relative terms, such as “below,” “lower,” “bottom,” “above,” “upper,” “top,” and the like, may be used for ease of description to describe one element's or feature's relationship to another element(s) or feature(s) as illustrated in the figures. Unless otherwise specified, any spatially relative terms used in this disclosure are intended to encompass different orientations of the materials in addition to the orientation as depicted in the figures. For example, if materials in the figures are inverted, elements described as “below” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (rotated ninety degrees, inverted, etc.) and the spatially relative descriptors used herein interpreted accordingly.

As used generally herein, the terms “level” and “elevation” are spatially relative terms used to describe one material's or feature's relationship to another material(s) or feature(s) as illustrated in the figures, using—as a reference point—the lowest illustrated surface of the structure that includes the materials or features. As used herein, a “level” and an “elevation” are each defined primarily by a horizontal plane parallel to a primary surface of the substrate or base structure on or in which the structure (that includes the materials or features) is formed. When used with reference to the drawings, “lower levels” and “lower elevations” are relatively nearer to the bottom-most illustrated surface of the respective structure, while “higher levels” and “higher elevations” are relatively further from the bottom-most illustrated surface of the respective structure.

As used herein with regard to describing a particular portion of a stack, the term “level” means and refers to the materials and/or structure(s) occupying a distinctive strata of the stack. Thus an “insulative level” of a stack means and refers to a strata of the stack that is primarily occupied (aside from patterning of the stack and materials formed to extend through or into such level) by insulative material(s) and/or insulative structure(s). A “non-conductive level” of a stack means and refers to a strata of the stack that is primarily occupied (aside from patterning of the stack and materials formed to extend through or into such level) by non-conductive material(s) and/or non-conductive structures. A “target level” of a stack means and refers to a particular strata of the stack, which strata has been selected for accomplishing some characteristic, such as a “target level” to which a contact extends for electrical communication during operation. As used herein, the terms “word line level” and “WL level” mean and refer to a strata of the stack that includes, at least in some horizontal area of the strata, conductive material(s)/structure(s) configured for operation as a word line (e.g., access line) of the block that includes the “word line level.” or “WL level.” One or more horizontal areas of the “word line level” or “WL level” may be occupied by non-conductive material(s)/structure(s).

As used herein, the term “depth” is a spatially relative term used to describe one material's or feature's relationship to other material(s) or feature(s) as illustrated in the figures, using—as a reference point—the highest illustrated surface of the structure (e.g., stack structure) that includes the materials or features. When used with reference to the drawings, a “depth” is defined by a horizontal plane parallel to the highest illustrated surface of the structure (e.g., stack structure) that includes the materials or features.

As used herein, the term “coupled to” means and refers to structures operatively connected with each other, such as electrically connected through a direct Ohmic connection or through an indirect connection (e.g., by way of one or more other structure(s)).

Unless otherwise specified, any spatially relative terms used in this disclosure are intended to encompass different orientations in addition to the orientation as depicted in the drawings. For example, the materials in the drawings may be inverted, rotated, etc., with the “upper” levels and elevations then illustrated proximate the bottom of the page, the “lower” levels and elevations then illustrated proximate the top of the page, the greatest “depths” extending a greatest vertical distance upward, and the “deep” stadiums being elevationally higher than the “shallow” stadiums.

As used herein, the terms “comprising,” “including,” “having,” and grammatical equivalents thereof are inclusive, open-ended terms that do not exclude additional, unrecited elements or method steps. These terms also include more restrictive terms “consisting of” and “consisting essentially of” and grammatical equivalents thereof. Therefore, a structure described as “comprising,” “including,” and/or “having” a material may be a structure that, in some embodiments, includes additional material(s) as well and/or a structure that, in some embodiments, does not include any other material(s). Likewise, a material (e.g., composition) described as “comprising,” “including,” and/or “having” a species may be a material that, in some embodiments, includes additional species as well and/or a material that, in some embodiments, does not include any other species.

As used herein, the term “may” with respect to a material, structure, feature, or method act indicates that such is contemplated for use in implementation of an embodiment of the disclosure and such term is used in preference to the more restrictive term “is” so as to avoid any implication that other, compatible materials, structures, features, and methods usable in combination therewith should or must be excluded.

As used herein, “and/or” means and includes any and all combinations of one or more of the associated listed items.

As used herein, the singular forms “a,” “an,” and “the” are intended to include the plural forms as well, unless the context clearly indicates otherwise.

As used herein, an “(s)” at the end of a term means and includes the singular form of the term and/or the plural form of the term, unless the context clearly indicates otherwise.

As used herein, the terms “configured” and “configuration” mean and refer to a size, shape, material composition, orientation, and arrangement of a referenced feature (e.g., region, material, structure, opening, assembly, device) so as to facilitate a referenced operation or property of the referenced feature in a predetermined way.

The illustrations presented herein are not meant to be actual views of any particular material, structure, sub-structure, region, sub-region, device, system, or stage of fabrication, but are merely idealized representations that are employed to describe embodiments of the disclosure.

Embodiments are described herein with reference to cross-sectional illustrations that are schematic illustrations. Accordingly, variations from the shapes of the illustrations as a result, for example, of manufacturing techniques and/or tolerances, are to be expected. Thus, embodiments described herein are not to be construed as limited to the particular shapes or structures as illustrated but may include deviations in shapes that result, for example, from manufacturing techniques. For example, a structure illustrated or described as box-shaped may have rough and/or nonlinear features. Moreover, sharp angles that are illustrated may be rounded; surfaces and features illustrated to be vertical may be non-vertical, bent, and/or bowed; and/or structures illustrated with consistent transverse widths and/or lengths throughout the height of the structure may taper in transverse width and/or length. Thus, the materials, features, and structures illustrated in the figures are schematic in nature and their shapes are not intended to illustrate the precise shape of a material, feature, or structure and do not limit the scope of the present claims.

The following description provides specific details, such as material types and processing conditions, to provide a thorough description of embodiments of the disclosed apparatus (e.g., devices, systems) and methods. However, a person of ordinary skill in the art will understand that the embodiments of the apparatus and methods may be practiced without employing these specific details. Indeed, the embodiments of the apparatus and methods may be practiced in conjunction with conventional semiconductor fabrication techniques employed in the industry.

The fabrication processes described herein do not form a complete process flow for processing apparatus (e.g., devices, systems) or the structures thereof. The remainder of the process flow is known to those of ordinary skill in the art. Accordingly, only the methods and structures necessary to understand embodiments of the present apparatus (e.g., devices, systems) and methods are described herein.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Depending on the specific material to be formed, the technique for depositing or growing the material may be selected by a person of ordinary skill in the art.

Unless the context indicates otherwise, the removal of materials described herein may be accomplished by any suitable technique including, but not limited to, etching (e.g., dry etching, wet etching, vapor etching), ion milling, abrasive planarization, or other known methods.

Unless the context indicates otherwise, while one or more areas (e.g., horizontal areas) of a structure are being impacted by processing acts (e.g., material removal acts, material formation acts) that are not described as impacting other areas of the structure, the other areas of the structure may, at such stage(s), be protected by, e.g., hard masks formed thereon, which masks may be removed prior to processing acts that are described as impacting the other areas.

In referring to the drawings, like numerals refer to like components throughout. The drawings are not necessarily drawn to scale.

With reference to FIG. 1 through FIG. 12B, illustrated are various stages of a method of forming a microelectronic device (e.g., a memory device, such as a 3D NAND Flash memory device), in accordance with embodiments of the disclosure.

Referring to FIG. 1, a method for forming a microelectronic device structure may include forming a precursor stack 102, which may also be referred to herein as a precursor “stacked structure” and/or as a precursor “tiered stack.” The precursor stack 102 may be formed on and supported by a substrate (e.g., a semiconductor substrate). A mask structure may also be formed on or over the precursor stack 102.

The precursor stack 102 includes a vertically repeated (e.g., in the Z-direction) pattern of material structures arranged in tiers 104. Each material structure may provide a level (e.g., distinctive strata) of the precursor stack 102. The precursor stack 102 may be formed in one or more so-called “decks,” with each “deck” including a group and repeated pattern of the tiers 104.

Each individual tier 104 may include at least one insulative structure 106 (e.g., at least one level of insulative material(s)) and at least one parsac structure 108 (e.g., at least one level of partially-sacrificial material(s)). In some embodiments, each tier 104 includes a single one of the insulative structures 106 and a single one of the parsac structures 108 vertically neighboring the one of the insulative structures 106 to provide a vertically alternating, interleaved arrangement of the insulative structures 106 and the parsac structures 108.

As described further below, at least some of the parsac structures 108 are eventually partially removed in certain area(s) (e.g., in WL-contact area(s)) and then conductive material(s) are formed in their place, such that the final stack structure includes “partially conductive levels” in the tiers of such area(s) (e.g., in WL-contact area(s)) of the stack. In other area(s) of the stack (e.g., in array area(s)), the parsac structures 108 may be substantially wholly removed and replaced with the conductive material(s).

The insulative structures 106 of the tiers 104 of the precursor stack 102 (and of the final stack) may be formed of and include (e.g., each be formed of and include) at least one electrically insulative material, such as a dielectric oxide material (e.g., silicon dioxide). In this and other embodiments described herein, the insulative material of the insulative structures 106 may be substantially the same as or different than other insulative material(s) of the microelectronic device structure. In some embodiments, the insulative structures 106 are formed of and include a dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and/or at least one dielectric carboxynitride material (e.g., SiOₓC_{z}N_{y}). In some embodiments, the insulative structures 106 are formed of and include a dielectric oxide material, such as SiOₓ (e.g., SiO₂).

Each of the insulative structures 106 may individually include a substantially homogeneous distribution of the at least one electrically insulative material, or a substantially heterogeneous distribution of the at least one electrically insulative material. In some embodiments, each of the insulative structures 106 of the tiers 104 of the precursor stack 102 (and final stack) exhibits a substantially homogeneous distribution of electrically insulative material. In additional embodiments, at least one of the insulative structures 106 of at least one of the tiers 104 of the precursor stack 102 (and final stack) exhibits a substantially heterogeneous distribution of at least one electrically insulative material. The insulative structures 106 may, for example, individually be formed of and include a stack (e.g., laminate) of at least two different electrically insulative materials.

The insulative structures 106 may, individually, be substantially planar, and may exhibit a desired thickness. Some or all of the insulative structures 106 may have the same (e.g., consistent) or different thicknesses (e.g., heights) as one another. In some embodiments, some of the insulative structures 106 (e.g., uppermost, lowest, and/or intermediate insulative structures 106 of the precursor stack 102 (and of the final stack) and/or of deck(s) of the precursor stack 102 (and the final stack)) are relatively thicker than others of the insulative structures 106 of the precursor stack 102 (and the final stack).

Material(s) of the parsac structures 108 may be selected or otherwise formulated to be selectively removable (e.g., selectively etchable) relative to the insulative structures 106. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. Accordingly, a material composition of the parsac structures 108 is different than a material composition of the insulative structures 106.

The parsac structures 108 of the tiers 104 of the precursor stack 102 (and of the final stack) may be formed of and include (e.g., each be formed of and include) at least one non-conductive material (e.g., as at least one electrically insulative material, such as one or more of the dielectric oxide material(s), dielectric nitride material(s), dielectric oxynitride material(s), and/or dielectric carboxynitride material(s) described above with regard to the insulative structures 106), selected or tailored to accommodate selective removal of the parsac structures 108 relative to the insulative structures 106, or vice versa. In some embodiments, the insulative structures 106 are each individually formed of and include a dielectric oxide material, such as SiOₓ (e.g., silicon dioxide (SiO₂)), and the parsac structures 108 are each individually formed of and include a dielectric nitride material, such as SiN_{y} (e.g., silicon nitride (Si₃N₄)).

Each of the parsac structures 108 may individually include a substantially homogeneous distribution of the non-conductive material(s) (e.g., the at least one additional electrically insulative material), or a substantially heterogeneous distribution of the non-conductive material(s) (e.g., the at least one additional electrically insulative material). In some embodiments, each of the parsac structures 108 of the tiers 104 of the precursor stack 102 (and of the final stack, where remnants of the parsac structures 108 are included) exhibits a substantially homogeneous distribution of non-conductive material(s) (e.g., the additional electrically insulative material). In additional embodiments, at least one of the parsac structures 108 of at least one of the tiers 104 of the precursor stack 102 (and of the final stack, where remnants of the parsac structures 108 are included) exhibits a substantially heterogeneous distribution of the non-conductive material(s) (e.g., the at least one additional electrically insulative material). The parsac structures 108 may, for example, be formed of and include a stack (e.g., laminate) of at least two different non-conductive material(s) (e.g., at least two different additional electrically insulative materials).

The parsac structures 108 may, individually, be substantially planar, and may exhibit a desired thickness. Some or all of the parsac structures 108 may have the same (e.g., consistent) or different thicknesses (e.g., heights) as one another or may have different thicknesses.

The precursor stack 102 (including the insulative structures 106 and the parsac structures 108) may be formed by forming the material structures (e.g., levels) of the precursor stack 102 sequentially (e.g., from lowest level of lowest tier 104 to highest level of highest tier 104) using conventional processes, including, but not limited to, physical vapor deposition (“PVD”), chemical vapor deposition (“CVD”), atomic layer deposition (“ALD”), and/or spin-coating. PVD includes, but is not limited to, one or more of sputtering, evaporation, and ionized PVD. Such processes are known in the art and, therefore, are not described in detail herein.

With reference to FIG. 2A and FIG. 2B, an arrangement of supports 202 may be formed in select areas of the precursor stack 102 (FIG. 1), such as in a WL-contact area 110 and, optionally, within an intermediate area 204 that is horizontally (X-direction) between the WL-contact area 110 and an array area 112. The supports 202 may substantially vertically extend through a whole height of the precursor stack 102 and to or into a base structure (e.g., substrate) below the precursor stack 102. The supports 202 may be formed of and include one or more conductive material(s), one or more non-conductive material(s), and/or one or more semiconductive materials. In some embodiments, the support 202 may be configured to be electrically non-operable, such that the supports 202 may not directly physically connect to other electrically operable, conductive components of the device.

The particular arrangement of the supports 202 may be tailored to provide sufficient structural support to the materials of the precursor stack 102 during subsequent processing. In some embodiments, the supports 202 may not be included in areas (e.g., horizontal areas) of the precursor stack 102 that will eventually be patterned to divide the precursor stack 102 into blocks. Thus, areas horizontally between block areas 206 may be substantially free of supports 202.

Within the WL-contact area 110, the precursor stack 102 is patterned (e.g., etched, in one or more material-removal acts) to form WL contact openings 208 extending substantially vertically through at least an upper portion of the precursor stack 102. The WL contact openings 208 extends to, and terminates at, various tier 104 elevations (e.g., various depths in the precursor stack 102, various elevations of the precursor stack 102, various levels of the precursor stack 102). Each WL contact opening 208 may be a discrete opening (e.g., a discrete high-aspect-ratio opening) extending through some number of the tiers 104 of the precursor stack 102, such that sidewalls of the WL contact openings 208 may be defined by the materials of the tiers 104 of the precursor stack 102.

Within an individual block area 206, the area horizontally (Y-direction) between neighboring WL contact openings 208 of the block area 206 may be substantially free of supports 202. Supports 202 in this between-contact area may not be necessary due to the methods of the embodiments disclosed herein, as discussed further below. Accordingly, this between-contact area may have a relatively lesser horizontal area (e.g., footprint) than if the area were tailored to accommodate inclusion of supports 202.

As the precursor stack 102 will eventually be divided into blocks, each block area 206 may include at least one WL contact opening 208 associated with each tier 104 that will eventually include a conductive structure providing a word line (WL) of that block of the device. Accordingly, across a width (X-direction) of the WL-contact area 110 of an individual block area 206, the WL contact openings 208 may extend to different levels (e.g., elevations) of the precursor stack 102. In some embodiments, some WL contact openings 208 may have a same extension height as one or more other of the WL contact openings 208.

In some embodiments, such as that illustrated in FIG. 2B, each block area 206 includes multiple (e.g., two) series (X-direction rows) of WL contact openings 208, and longitudinally neighboring (Y-direction) WL contact openings 208 may extend to different levels of the precursor stack 102. For example, one of longitudinally neighboring WL contact openings 208 may extend to a tier 104 elevation of “N” (such as to a tenth tier 104 from the top of the precursor stack 102) and another of the longitudinally neighboring WL contact openings 208 may extend to a tier 104 elevation of “N−2” tiers (such as to a twelfth tier 104 from the top of the precursor stack 102). In some embodiments, neighboring (Y-direction) block areas 206 are patterned with substantially mirrored WL contact openings 208, as illustrated in the WL-contact area 110 of FIG. 2B.

In the array area 112, an arrangement of pillars 210 is formed to substantially vertically extend through the precursor stack 102. The pillars 210 may include, in at least one sub-region thereof, a channel material (e.g., a semiconductor material). The pillars 210 may be configured to individually provide a vertical string of memory cells in the final device. The pillars 210 may be grouped within the block areas 206.

Regions between (Y-direction) the block areas 206 may be designated for the feature(s) by which the precursor stack 102 (and, eventually the final stack) will be divided into blocks. In some embodiments, as discussed further below, such features may be formed in elongate slits formed through the precursor stack 102 in the between-block area, which area may be referred to herein as an “inter-block” area (e.g., the area horizontally (Y-direction) between neighboring block areas 206). In other embodiments, the features may include inter-block pillars 212, such as illustrated in FIG. 2A and FIG. 2B.

A row of the inter-block pillars 212 may extend horizontally along the width (X-direction) of each inter-block area (between neighboring block areas 206), at least in the array area 112 and the WL-contact area 110. In some embodiments, the row of the inter-block pillars 212 continues through the intermediate area 204. In other embodiments, no inter-block pillars 212 are included in the intermediate area 204.

In some embodiments, the inter-block pillars 212 are formed of (e.g., consist substantially of, consist of) non-conductive material(s) (e.g., an insulative liner (e.g., an oxide material) about another insulative core). In other embodiments, the inter-block pillars 212 may, optionally, be formed of and include some or all of the materials and features of the pillars 210 of the block area 206, though the inter-block pillars 212 may not be configured for electrical functionality in the final device. Accordingly, the such inter-block pillars 212 may be formed through the precursor stack 102 concurrently with, before, or subsequent to formation of the pillars 210 in the block areas 206 of the array area 112.

The materials and structures of the inter-block pillars 212 in the array area 112 and in the WL-contact area 110 may be substantially sacrificial, as described further below. In embodiments including inter-block pillars 212 in the intermediate area 204, the materials and structures of the inter-block pillars 212 in the intermediate area 204 may, optionally, also be sacrificial.

With returned reference FIG. 2B and the WL contact openings 208 formed in the WL-contact area 110, each WL contact opening 208 may be formed to initially terminate at or in a respective one of the insulative structures 106, such that a base of the WL contact opening 208 may expose a portion of the respective one of the insulative structures 106.

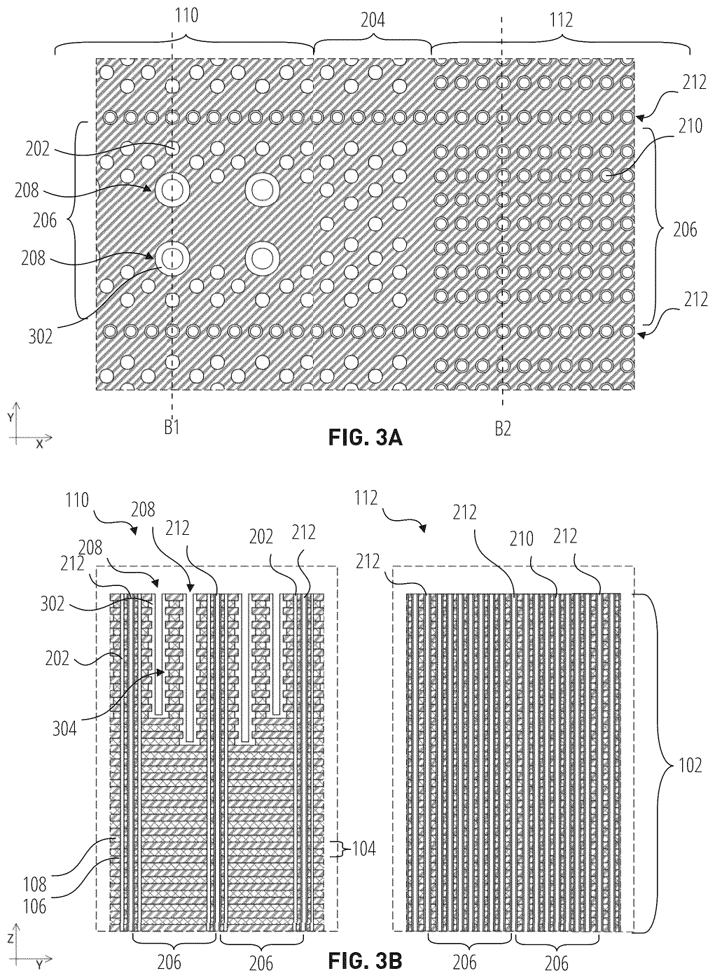

With reference to FIG. 3A and FIG. 3B, a liner material 302 may be formed (e.g., conformally deposited) in the WL contact openings 208, on and over exposed surfaces of the tiers 104 of the precursor stack 102 (e.g., exposed sidewalls surfaces of the insulative structures 106 and the parsac structures 108 and the exposed horizontal surfaces of the insulative structures 106 (or parsac structures 108) at the base of the WL contact openings 208). In some embodiments, the liner material 302 may also be formed over an upper surface of the precursor stack 102.

Optionally, in some embodiments, prior to forming the liner material 302, the sidewalls of the parsac structures 108 may be selectively etched relative to the insulative structures 106 so as to recess 304 the parsac structures 108 relative to the insulative structures 106 within the WL contact openings 208. In other embodiments, this recess 304 formation is omitted, and the sidewalls of the parsac structures 108 and the insulative structures 106 within the WL contact openings 208 may substantially vertically align.

The liner material 302 may be formed of and include at least one insulative (e.g., dielectric) material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and/or at least one dielectric carboxynitride material (e.g., SiOₓC_{z}N_{y}).

A material composition of the liner material 302 may be selected such that the insulative structures 106 and the parsac structures 108 of the precursor stack 102 are selectively etchable relative to the liner material 302. Accordingly, a material composition of the liner material 302 may be different than a material composition of the insulative structures 106 and may be different than a material composition of the parsac structures 108. For example, in embodiments in which the insulative structures 106 comprise an insulative oxide material and in which the parsac structures 108 comprise an insulative nitride material, the liner material 302 may include and be formed of at least one dielectric oxynitride material and/or at least one dielectric carboxynitride material.

The liner material 302 may individually include a substantially homogeneous distribution of the at least one dielectric material, or a substantially heterogeneous distribution of the at least one dielectric material. In some embodiments, the liner material 302 exhibits a substantially homogeneous distribution of dielectric material. In additional embodiments, the liner material 302 exhibits a substantially heterogeneous distribution of dielectric material. The liner material 302 may, for example, be formed of and include a stack (e.g., laminate) of at least two different dielectric materials.

The liner material 302 may be formed using conventional processes (e.g., at least one conventional conformal deposition process, such as one or more of a conventional conformal CVD process and a conventional ALD process) and conventional processing equipment, which are not described in detail herein.

The liner material 302 may be formed to any suitable thickness so as to not substantially fill or close off the WL contact openings 208. Alternatively, the liner material 302 may be formed to initially substantially fill the WL contact openings 208 and may then a portion of the liner material 302 may be removed (e.g., etched) to form a discrete opening extending through the liner material 302 in each WL contact opening 208.

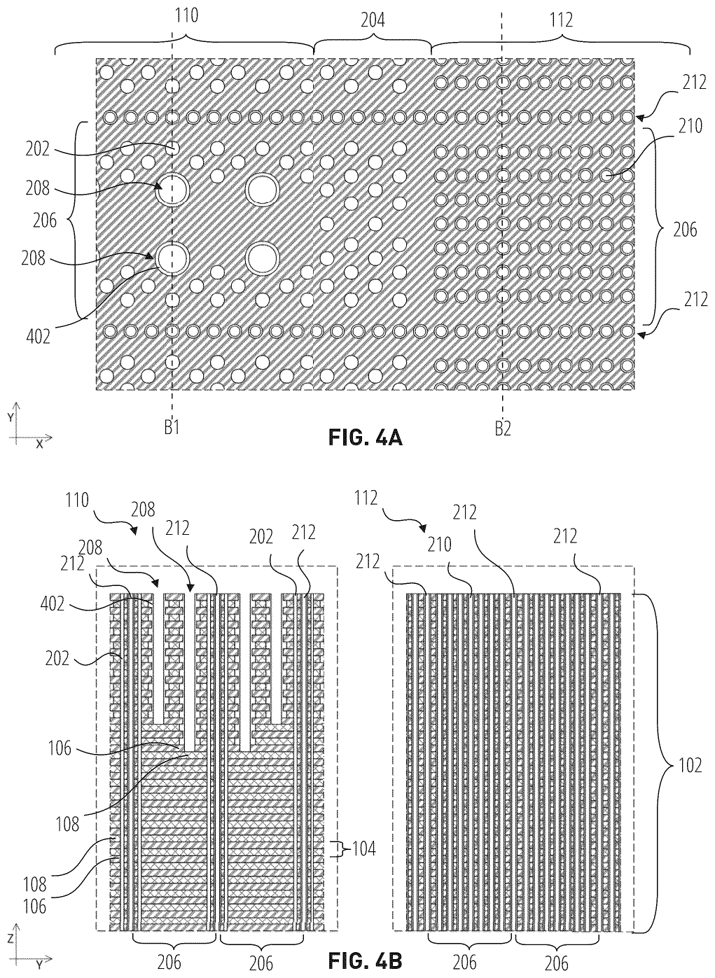

With reference to FIG. 4A and FIG. 4B, portions of the liner material 302 (FIG. 3A, FIG. 3B) at lower vertical boundaries (e.g., bottoms, floors, lower ends) of the WL contact openings 208 (if still present at this stage) may be removed to form liner structures 402 within the WL contact openings 208. Removing the lower portion of the liner material 302 may, in some embodiments, also thin the liner material 302 along the sidewalls in the WL contact openings 208. In embodiments in which formation of the liner material 302 formed the liner material 302 outside of the boundaries (e.g., upper vertical boundaries, horizontal boundaries) of the WL contact openings 208, this excess liner material 302 may also be removed before, after, or while removing the lower portions of the liner material 302 in the WL contact openings 208.

With the WL contact openings 208 having initially been formed to terminate at or in insulative structures 106, the areas of the insulative structure 106 immediately below the base opening of the liner structures 402 may be removed (e.g., selectively etched, relative to the liner material 302 of the liner structures 402) to expose an area of the parsac structure 108 at the base of each WL contact opening 208, as illustrated in the WL-contact area 110 of FIG. 4B.

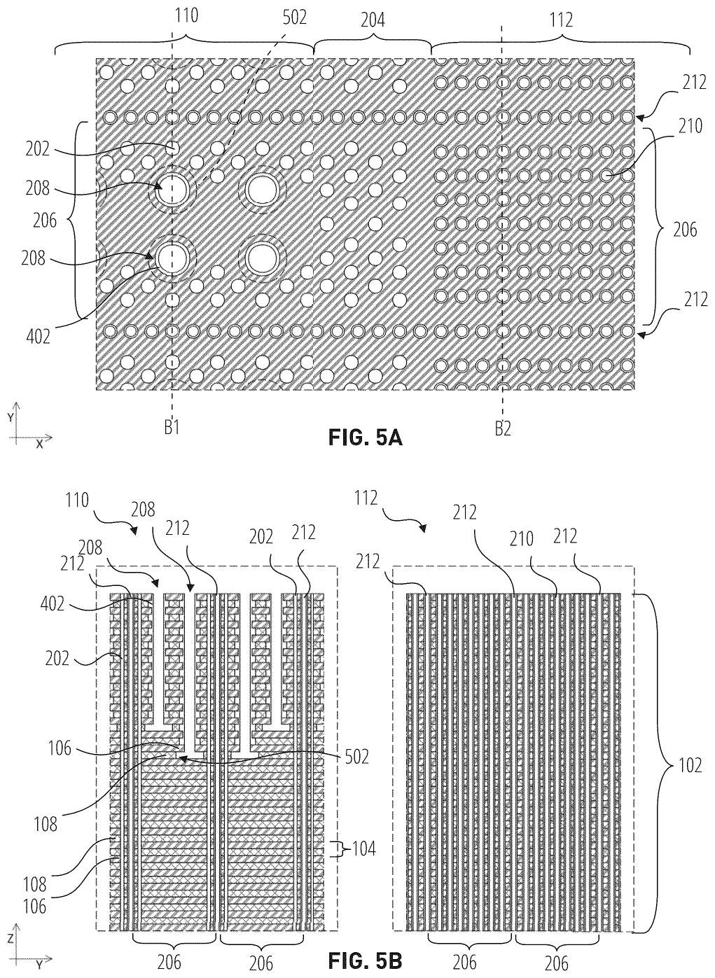

With reference to FIG. 5A and FIG. 5B, in some embodiments, the area of the parsac structure 108 exposed at the base of the WL contact opening 208, may be removed along with horizontally adjacent areas of the parsac structure 108 to form an expanded base 502 at the base of each WL contact opening 208. For example, the parsac structure 108 at the base of the WL contact opening 208 may be selectively etched relative to the liner structure 402 and, in some embodiments, relative to the insulative structure 106 adjacent the base of the WL contact opening 208. Due to the presence of the liner structure 402, other parsac structures 108 along the WL contact opening 208 may be protected from removal (e.g., etching).

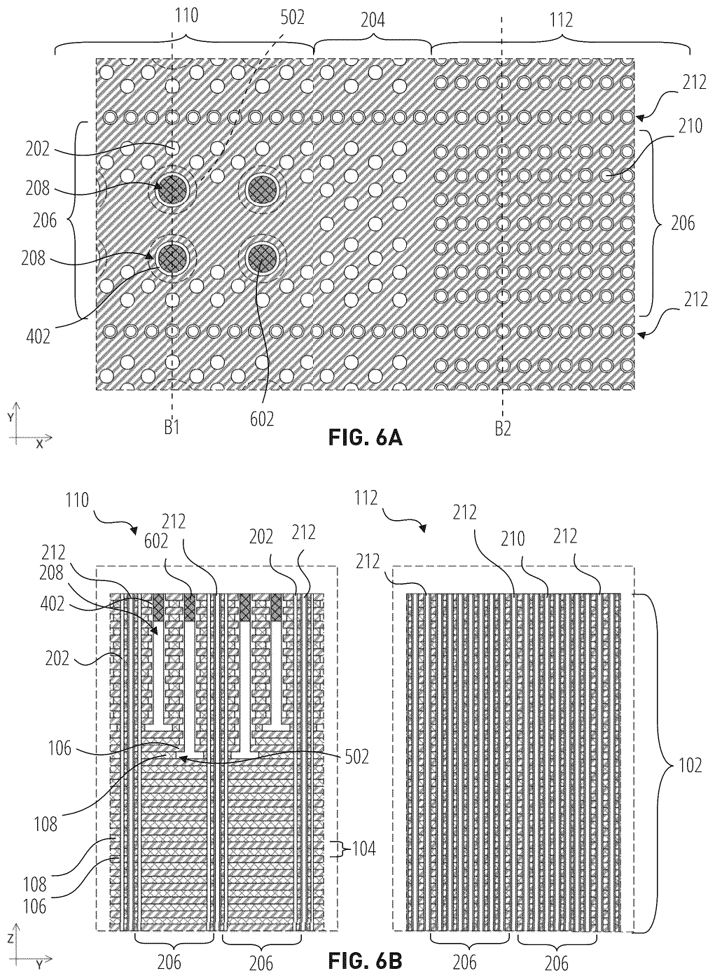

With reference to FIG. 6A and FIG. 6B, after at least exposing a target parsac structure 108 at the base of each WL contact opening 208 and, in some embodiments (such as illustrated in FIG. 5A and FIG. 5B), after forming the expanded bases 502 of the WL contact openings 208, a sacrificial material is formed (e.g., deposited) in or on the WL contact openings 208, forming a plug 602 in or on each WL contact opening 208. In some embodiments, the plug 602 does not wholly fill the WL contact opening 208, but closes off at least the expanded base 502 so that the parsac structure 108 at the base of each WL contact opening 208 is no longer exposed. In other embodiments, the plug 602 is formed to wholly fill the WL contact opening 208 and, if present, the expanded base 502.

The plug 602 may be formed using conventional processes including, but not limited to, physical vapor deposition (“PVD”), chemical vapor deposition (“CVD”), atomic layer deposition (“ALD”), and/or spin-coating. PVD includes, but is not limited to, one or more of sputtering, evaporation, and ionized PVD. Such processes are known in the art and, therefore, are not described in detail herein.

The plug 602 may be formed of and include a material formulated or otherwise selected so as to be selectively etchable relative to the insulative structures 106 and the liner structures 402. In some embodiments, the plug 602 is formed of and includes a polycarbon material.

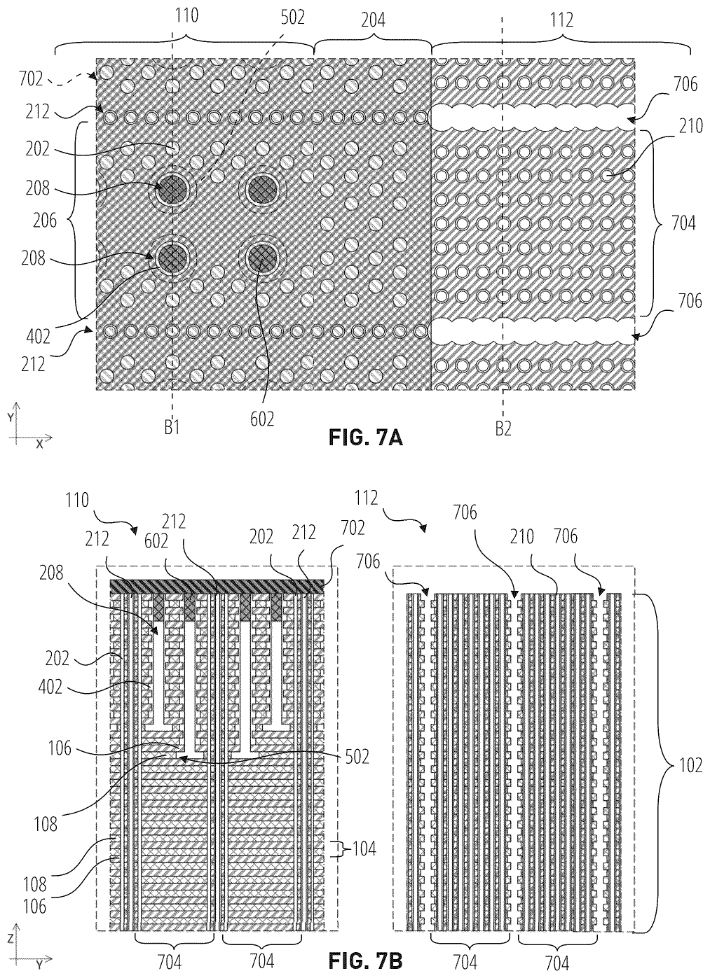

With reference to FIG. 7A and FIG. 7B, after forming the plugs 602, a mask structure 702 may be formed over the WL-contact area 110 and, in some embodiments, over all or part of the intermediate area 204. The mask structure 702 may also be formed over the block 704 areas in the array area 112 to cover the pillars 210. At least the inter-block pillars 212 of the array area 112 may be exposed through the mask structure 702.

The mask structure 702 may be formed of and include at least one material (e.g., at least one hard mask material) suitable for use as a protective mask for the WL-contact area 110 (and, in some embodiments, the block areas 206) during material removal processes carried out in the inter-block area(s) of the array area 112. By way of non-limiting example, the mask structure 702 may be formed of and include one or more hard mask materials having etch selectivity relative to the materials of the precursor stack 102 (including the insulative structures 106 and the parsac structures 108). In some embodiments, the mask structure 702 comprises one or more of amorphous carbon and doped amorphous carbon (e.g., boron-doped amorphous carbon, such as boron-doped amorphous carbon comprising at least 1 weight percent (wt %) boron and at least 20 wt % carbon, such as between about 1 wt % boron and about 40 wt % boron, and between about 99 wt % carbon and about 60 wt % carbon). The mask structure 702 may be homogeneous (e.g., may include only one material layer), or may be heterogeneous (e.g., may include a stack exhibiting at least two different material layers). In addition, the mask structure 702 may exhibit any thickness suitable for the mask structure 702 to survive, at least in some thickness, the material removal acts to be performed in the array area 112. For example, and without limitation, the mask structure 702 may be formed with a thickness ranging from about 1 nanometer (nm) to about 1,000 nm.

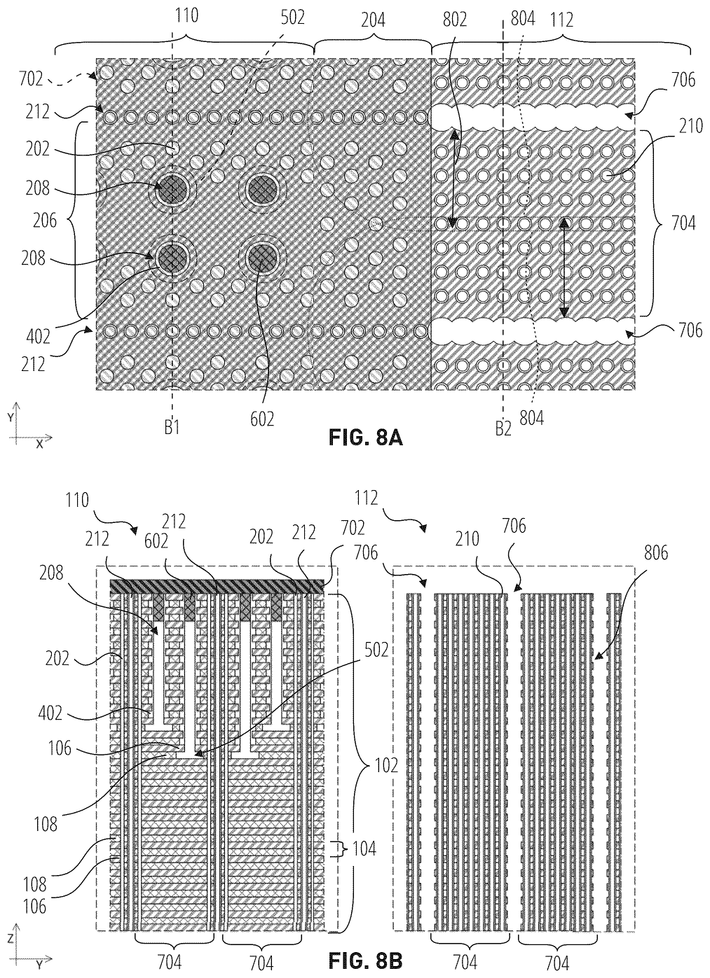

For ease of illustration of lower features, the mask structure 702 is illustrated in partial transparency in the WL-contact area 110 and the intermediate area 204 of FIG. 8A, and also in subsequent illustrations that include the mask structure 702.

The mask structure 702 may be formed using conventional processes including, but not limited to, physical vapor deposition (“PVD”), chemical vapor deposition (“CVD”), atomic layer deposition (“ALD”), and/or spin-coating. PVD includes, but is not limited to, one or more of sputtering, evaporation, and ionized PVD. Such processes are known in the art and, therefore, are not described in detail herein.

With the mask structure 702 protecting the WL-contact area 110 (and, in some embodiments, also the block areas 206 in the array area 112), the material(s) of the inter-block pillars 212 of the array area 112 may be removed (e.g., etched) and surrounding insulative structures 106 recessed (e.g., etched). Accordingly, each inter-block pillar 212 of the array area 112 may be converted into an opening extending through the height of the precursor stack 102 and merging with (e.g., communicating with) the horizontally neighboring (Y-direction) openings of likewise removed inter-block pillars 212. This may form an inter-block opening 706 along the width (X-direction) of each inter-block area (e.g., between block areas 206) in the array area 112. The resulting inter-block openings 706 may be substantially elongate and may have non-planar (e.g., scalloped) sidewalls. The inter-block openings 706 divide the precursor stack 102 of the array area 112 into blocks 704. Each block 704 may be formed in a respective one of the block areas 206.

In other embodiments, the inter-block openings 706 are each formed as an elongate opening (e.g., slit) with substantially planar sidewalls.

The inter-block openings 706 may extend horizontally (X-direction) along substantially all or a substantial majority of the array area 112, as illustrated in FIG. 7A. In some embodiments, the inter-block openings 706 may not extending horizontally wholly through or substantially into the intermediate area 204, at this stage, so as to facilitate, in later stage(s), different exhumation and replacement processes in the WL-contact area 110 compared to the array area 112 (e.g., later substantially complete exhumation and replacement of the parsac structures 108 in the array area 112 and only partial exhumation and replacement of the parsac structures 108 in the WL-contact area 110). The inter-block openings 706 in the WL-contact area 110 may be in horizontal alignment (X-direction) with the remaining inter-block pillars 212 of the WL-contact area 110 and/or the intermediate area 204. In other embodiments, the inter-block openings 706 are initially formed, at this stage, to also extend through or into the intermediate area 204.

The inter-block openings 706 may extend vertically through a whole of the height of the precursor stack 102. The lateral (X-direction) and longitudinal (Y-direction) dimensions of the inter-block openings 706 may be tailored to accommodate the subsequent removal of select portions of the parsac structures 108 and formation of conductive structures in their place, as described further below.

With reference to FIG. 8A and FIG. 8B, the inter-block openings 706 of the array area 112 may provide access to substantially remove (e.g., exhume) the parsac structures 108 from substantially the whole of the array area 112. The removal (e.g., exhumation) process may be tailored (e.g., in time, in etchant chemistry, or both) so that, in the array area 112, the parsac structures 108 removal is substantially complete. For example, the removal (e.g., exhumation) may be tailored so that a distance 802 (i.e., a horizontal distance from the inter-block opening 706) in which parsac structures 108 are removed is at least long enough to reach and remove the material(s) of the parsac structures 108 at longitudinal (Y-direction) center of the block 704. The distance 802 may be tailored so that there is some amount of overlap (Y-direction) to ensure the substantial total removal of the parsac structures 108 from the whole length (Y-dimension) of the block 704 in the array area 112.

Due to tailored timing of the removal (e.g., exhumation) process and/or due to the inter-block openings 706 terminating at or in the intermediate area 204, the removal (e.g., exhumation) of the parsac structures 108 may extend a scope 804 (e.g., a shape defined by a periphery of the distance 802) that does not reach substantially into the WL-contact area 110 (e.g., does not reach (X-direction) the WL contact openings 208). Accordingly, at this stage, the parsac structures 108 (and the repeated tiers 104 of the precursor stack 102) may remain in the WL-contact area 110, while, in the array area 112, voids 806 may occupy the levels previously occupied by the parsac structures 108. The presence of the pillars 210 may inhibit the still-remaining insulative structures 106 from collapsing or sagging into the voids 806 in the array area 112.

Notably, because the pillars 210 are discrete (e.g., cylindrical) structures, their presence does not form a barrier to removal of the parsac structures 108. Therefore, though FIG. 8B illustrates a row of vertical pillars 210 between neighboring inter-block openings 706, the voids 806 are substantially continuous, at each respective level in the stack, throughout the array area 112.

Because the parsac structures 108 are substantially wholly removed from the array area 112, the material-removal process carried out in the array area 112 may be referred to herein as a “full exhumation” process.

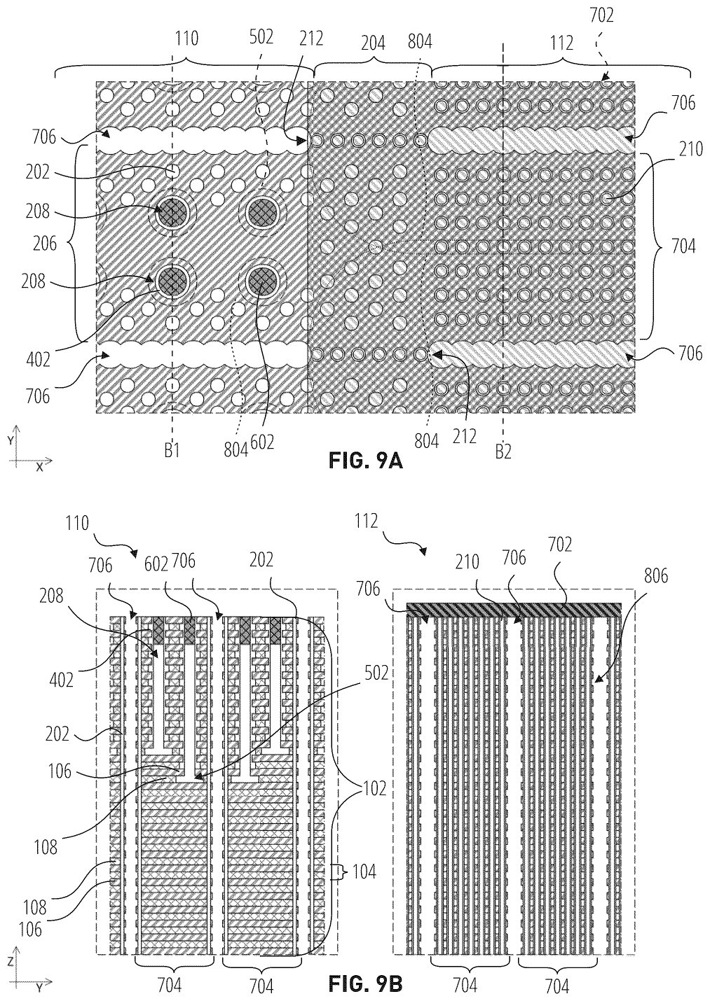

After the full exhumation in the array area 112, the mask structure 702 may be removed from the WL-contact area 110 and may be reformed—as illustrated in FIG. 9A and FIG. 9B—on the array area 112 and, in some embodiments, also over all or part of the intermediate area 204. Removing the mask structure 702 from the WL-contact area 110 exposes the inter-block pillars 212 of the WL-contact area 110.

The inter-block pillars 212 of the WL-contact area 110 may then be removed (e.g., etched) and surrounding insulative structures 106 partially recessed (e.g., etched) to form inter-block openings 706 in the WL-contact area 110, in a similar manner to the formation of the inter-block openings 706 of the array area 112, described above.

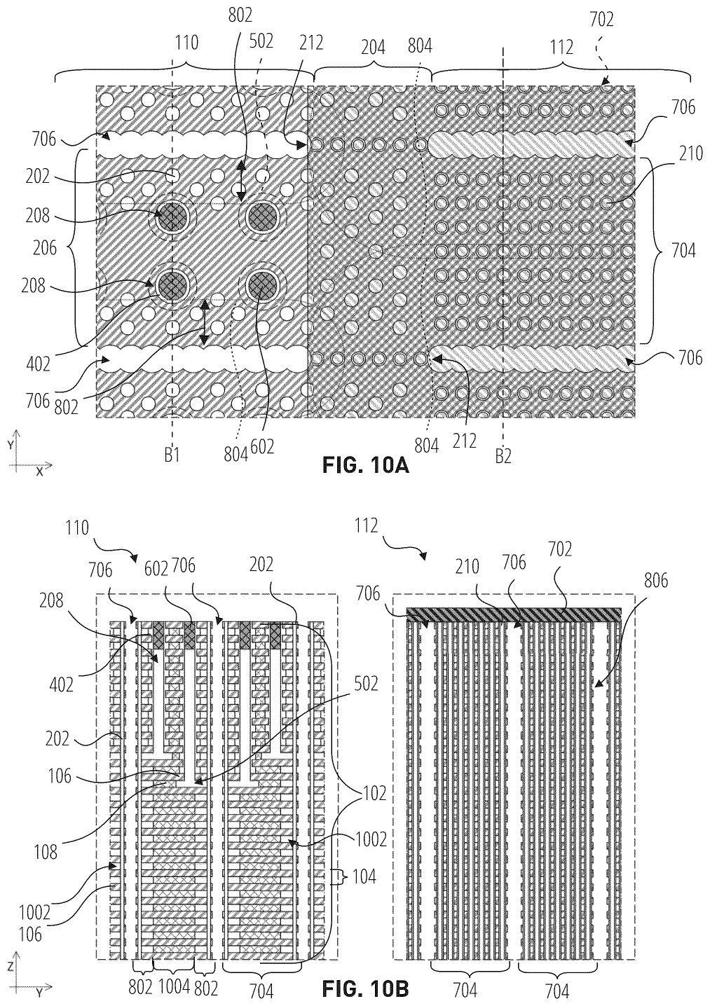

With reference to FIG. 10A and FIG. 10B, via the inter-block openings 706 in the WL-contact area 110, another material-removal (e.g., exhumation) process is carried out with a more limited duration or other tailoring so as to only partially remove the parsac structures 108 from the WL-contact area 110. For example, the material-removal (e.g., exhumation) may be tailored so that the parsac structures 108 are removed—forming additional voids 1002—is a scope 804 (e.g., defined by distance 802 from the inter-block opening 706 of the WL-contact area 110) that does not reach to or past the longitudinal (Y-direction) center of the block 704. In embodiments in which the WL contact openings 208 have extended expanded bases 502, the exhumation process may be tailored to ensure that the distance 802 (and scope 804) at least reach the side of the expanded base 502 that is nearest the inter-block opening 706. Accordingly, the exhumation process exposes each respective base (expanded base 502) of the WL contact openings 208 to a respective one of the additional voids 1002. Accordingly, at this stage, each WL contact opening 208 communicates to an adjacent inter-block opening 706 at a target level (e.g., via one additional void 1002) of the precursor stack 102.

Because the parsac structures 108 are only partially removed in the WL-contact area 110, there is at least one area 1004 of the block 704 (e.g., portion(s) of the WL-contact area 110) that retains the materials, structures, and vertically repeated tier 104 pattern of the precursor stack 102. The area 1004 thus include both the insulative structures 106 and remnants of the parsac structures 108. The area 1004 may be an area that extends horizontally (Y-direction) between neighboring WL contact openings 208 of the block 704. In elevations below the WL contact openings 208, the area 1004 may be at least partially overlapped by the WL contact openings 208.

By retaining some amount of the parsac structures 108 in the WL-contact area 110, the area in which the additional voids 1002 are vertically between insulative structures 106 is limited to only the scope 804, defined by the exhumation distance 802, adjacent the inter-block openings 706. The distance 802 may be a relatively minor distance. The lesser extension of the additional voids 1002 may lessen the likelihood of structural deformation (e.g., sagging, bending, collapse) of the insulative structures 106 into the additional voids 1002 (e.g., along the inter-block openings 706), compared to the likelihood of deformation of the insulative structures 106 if the parsac structures 108 had been wholly removed throughout the WL-contact area 110. Accordingly, supports 202 may not be necessary to include in the area 1004 (and immediately adjacent to the area 1004) that has the remnants of the parsac structures 108. In some embodiments, some supports 202 or some portion of supports 202 are included in the area 1004 (e.g., along the periphery of the scope 804).

Supports 202 may be included adjacent the inter-block openings 706, and these supports 202 may also inhibit the insulative structures 106 from deforming into the additional voids 1002 along the inter-block openings 706. Notably, because the supports 202 may be discrete (e.g., cylindrical) structures, their presence in the scope 804 (e.g., along the distance 802) does not form a barrier to the removal of the parsac structures 108 from this area (e.g., the scope 804). Therefore, though FIG. 10B illustrates one of the supports 202 horizontally between the WL contact opening 208 and the inter-block opening 706, the additional voids 1002 may be continuous around such supports 202.

Because supports 202 may not be necessary (e.g., may be optional) within (e.g., and immediately adjacent to) the area 1004 retaining remnants of the parsac structures 108, the fabrication of the device may be relatively more reliably performed even without requiring center-of-block footprint area to be made available to supports 202. Accordingly, the blocks 704 may be designed to have a relatively lesser length (Y-direction) and horizontal area, which may accommodate device scaling.

The exhumation process being tailored to only partially remove the parsac structures 108 from the WL-contact area 110 may be referred to herein as a “partial exhumation” process. Notably, the partial exhumation connects the inter-block openings 706 to the WL contact openings 208 via the additional voids 1002 at substantially only the base (e.g., the expanded base 502) of the WL contact openings 208. The liner structures 402 physically separate the additional voids 1002 from reaching the WL contact openings 208 at the previous parsac structure 108 levels above the base of the WL contact openings 208.

After the partial exhumation in the WL-contact area 110, the mask structure 702 may be removed from the array area 112 and, if present, from the intermediate area 204.

In embodiments in which the inter-block pillars 212 were initially formed in the intermediate area 204, the inter-block pillars 212 may remain in the intermediate area 204 in the final device. Unlike the pillars 210 of the block 704 in the array area 112, however, the inter-block pillars 212 remaining in the intermediate area 204 may be non-functional, e.g., not electrically connected with other electrically active features (e.g., word lines (e.g., access lines), contacts) of the device. A row of inter-block pillars 212 in the intermediate area 204, along with the horizontally adjacent inter-block openings 706 of the WL-contact area 110 and the array area 112, respectively, may together effectively separate the stack (including the portions with the structure of the precursor stack 102 and the portions with the structure of the stack 1102) into neighboring blocks 704.

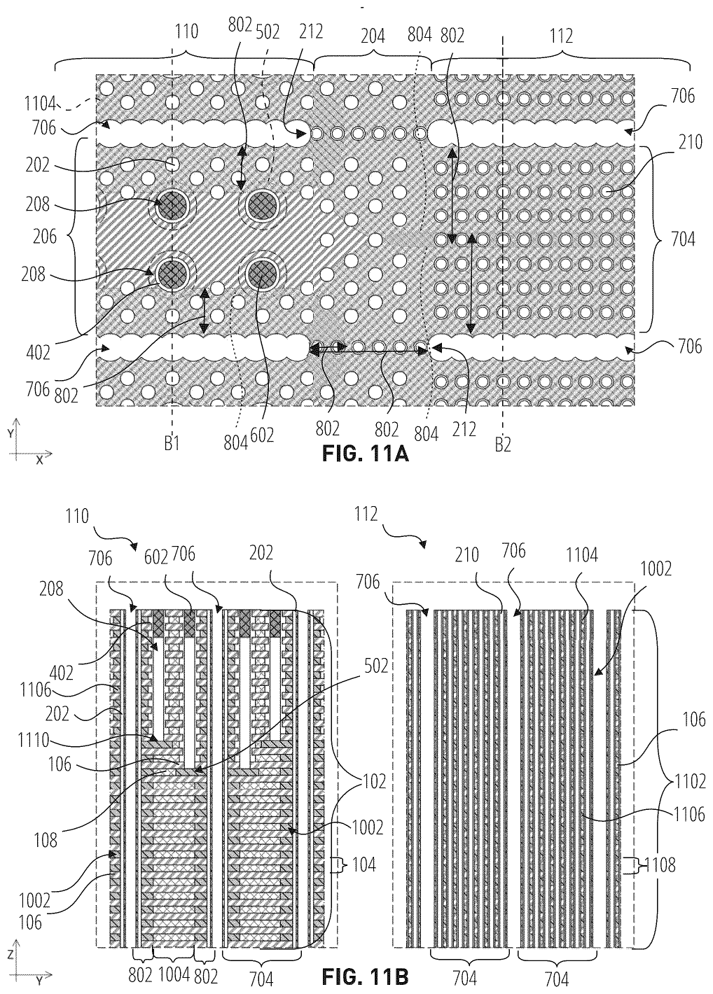

With reference to FIG. 11A and FIG. 11B, the inter-block openings 706 of the WL-contact area 110 and the array area 112 may be used to form conductive material(s) 1104 in the voids 806 (in the array area 112) and the additional voids 1002 (in the WL-contact area 110) previously occupied by the parsac structures 108. Thus, conductive structures 1106 may be formed in place of the removed parsac structures 108 or removed portions of the parsac structures 108. Accordingly, in the areas in which the parsac structures 108 were removed (e.g., the scope 804), a stack 1102 structure is formed with a vertically repeated pattern of tiers 1108 that includes at least one of the insulative structures 106 and at least one of the conductive structures 1106. In the other areas 1004, the structure of the precursor stack 102 remains. Accordingly, at this stage, a stack structure includes a vertically repeated tier pattern, with each tier including at least one insulative level (e.g., formed by one of the insulative structures 106) and at least one other level that is partially conductive (e.g., formed by one of the conductive structures 1106) and at least partially non-conductive (e.g., formed by remnants of one of the parsac structures 108).

The conductive material(s) 1104 of the conductive structures 1106 may include one or more conductive materials, such as one or more of: at least one metal (e.g., one or more of tungsten, titanium, nickel, platinum, rhodium, ruthenium, iridium, aluminum, copper, molybdenum, silver, gold), at least one alloy (e.g., an alloy of one or more of the aforementioned metals), at least one metal-containing material that includes one or more of the aforementioned metals (e.g., metal nitrides, metal silicides, metal carbides, metal oxides, such as a material including one or more of titanium nitride (TiN), tantalum nitride (TaN), tungsten nitride (WN), titanium aluminum nitride (TiAlN), iridium oxide (IrOₓ), ruthenium oxide (RuOₓ), alloys thereof), at least one conductively-doped semiconductor material (e.g., conductively-doped silicon, conductively-doped germanium, conductively-doped silicon germanium, conductively-doped polysilicon), and at least one other material exhibiting electrical conductivity. In some embodiments, the conductive material(s) 1104 include—and the conductive structures 1106 include and are formed of—at least one of the aforementioned conductive materials along with at least one additional of the aforementioned conductive materials formed as a liner.

The conductive structures 1106 may have substantially the same structure (e.g., thicknesses, width, planarity) as the parsac structures 108 or portions of the parsac structures 108 that the conductive structures 1106 effectively replace. Accordingly, the conductive structures 1106 horizontally extend throughout the scope 804 in the WL-contact area 110 and throughout the array area 112. The conductive structures 1106 may extend the distance 802 from the inter-block openings 706, except where such distance provides some overlap with the distance 802 from an opposite inter-block opening 706. Where there is some overlap between distances 802 (e.g., as illustrated near the center of the block 704 in the array area 112 of FIG. 11A) or where the distances 802 at least meet one another in the longitudinal center of the block 704, longitudinally neighboring (Y-direction) conductive structures 1106, once formed, effectively join together to provide a continuous region of conductive material(s) across the length (Y-direction) of the block 704. Where the distances 802 do not meet or overlap with one another (e.g., as illustrated in the WL-contact area 110 of FIG. 11A), each conductive structure 1106—extending horizontally from the periphery of the inter-block openings 706—is horizontally surrounded along at least a portion of its periphery (e.g., a portion adjacent the WL contact openings 208 of the block 704) by a remnant parsac structure 108 as in the area 1004 illustrated in FIG. 11B.

Moreover, in the WL-contact area 110, at target levels of the stack 1102—which target levels are at the elevations of the bases (e.g., expanded bases 502), respectively, of the WL contact openings 208—the conductive structures 1106 further extend horizontally (Y-direction) the distance of the base (e.g., expanded base 502) of the WL contact openings 208. This greater extension provides a landing area 1110 for the WL contact to be subsequently formed in the WL contact opening 208. Thus, at the base (e.g., expanded base 502) of a respective one of the WL contact openings 208, the conductive structure 1106 providing the landing area 1110 extends a greater horizontal distance from the inter-block opening 706 than the conductive structures 1106 of stack 1102 levels above the landing area 1110. Depending on the scope 804 of the partial exhumation, the conductive structure 1106 providing the landing area 1110 may also extend a greater horizontal distance from the inter-block opening 706 than the conductive structures 1106 of the levels of the stack 1102 below the landing area 1110, as illustrated in FIG. 11B.

With continued reference to FIG. 11A, the full exhumation process and the partial exhumation process, as well as the positioning and dimensions of the inter-block openings 706, may be tailored to ensure there is some horizontal connection or overlap of the scope 804 (and thus the extent of the conductive structures 1106) of the WL-contact area 110 and the scope 804 (and thus the extent of the conductive structures 1106) of the array area 112. Therefore, after the formation of the conductive material(s) 1104, each conductive structure 1106 (e.g., at a respective tier level) is substantially continuous across a width of the block 704, including through the array area 112, the WL-contact area 110, and the intermediate area 204.

A respective conductive structure 1106 of the stack (e.g., including the areas with the structure of stack 1102 and the areas with the structure of the precursor stack 102) is substantially continuous across the horizontal area (X-direction and Y-direction) of the array area 112 of the block 704 (where not otherwise interrupted by pillars 210). The respective conductive structure 1106 also includes two so-called “bridges” that extend horizontally (X-direction) from the array area 112 (e.g., whether from an edge of the array area 112 or from some edge in the intermediate area 204), along the X-direction-extending sides of the block 704. Each bridge may be adjacent one of the inter-block openings 706 that (along with inter-block pillars 212 in the intermediate area 204) define the block 704.

With each conductive-material-including level of the stack providing a substantially continuous region of conductive material(s) across the block 704, an electrical connection at one area (e.g., the landing area 1110 in the WL-contact area 110) of the conductive structure 1106 along the width of the block 704 provides an effective electrical connection with other areas of the conductive structure 1106 (e.g., areas in the array area 112) along the block 704. Moreover, because the conductive structures 1106 are in operable connection with the pillars 210 in the array area 112, forming an electrically operable contact (e.g., WL contact) to a target conductive structure 1106 (e.g., the conductive structure 1106 providing the landing area 1110) in the WL-contact area 110 provides effective electrical communication to a target memory cell of an electrically operated pillar 210 in the array area 112.

To provide the landing areas 1110 for the WL contacts, the formation of the conductive material(s) 1104 in the additional voids 1002 of the WL-contact area 110 forms the conductive material(s) 1104 to extend into and fill the expanded bases 502 of the WL contact openings 208. That is, by ensuring that the distance 802 of the parsac structure 108 exhumation in the WL-contact area 110 at least reached the expanded bases 502, the additional voids 1002 connect to the expanded bases 502 so that the expanded bases 502 are accessible to be filled with the conductive material(s) 1104. Due to the presence of the liner structure 402 in the WL contact openings 208, only the level of the base (e.g., the expanded base 502) of the WL contact opening 208 is accessible during formation of the conductive material(s) 1104. Therefore, for each individual WL contact opening 208, one conductive structure 1106 is formed to extend along the base (e.g., the expanded base 502) of the WL contact opening 208, providing the landing area 1110 of the formed conductive structure 1106 at that target level (e.g., the level of the base of the WL contact opening 208).

In some embodiments, the conductive material(s) 1104 (and, therefore, the conductive structure 1106) at the target level may be formed to extend some distance vertically upward into the WL contact opening 208 without detracting from the methods, structures, and devices herein. Accordingly, the conductive structure 1106 at the target level (e.g., the base level of the WL contact opening 208) may or may not include an upward extension at the base of the WL contact opening 208 and yet otherwise may be substantially planar.

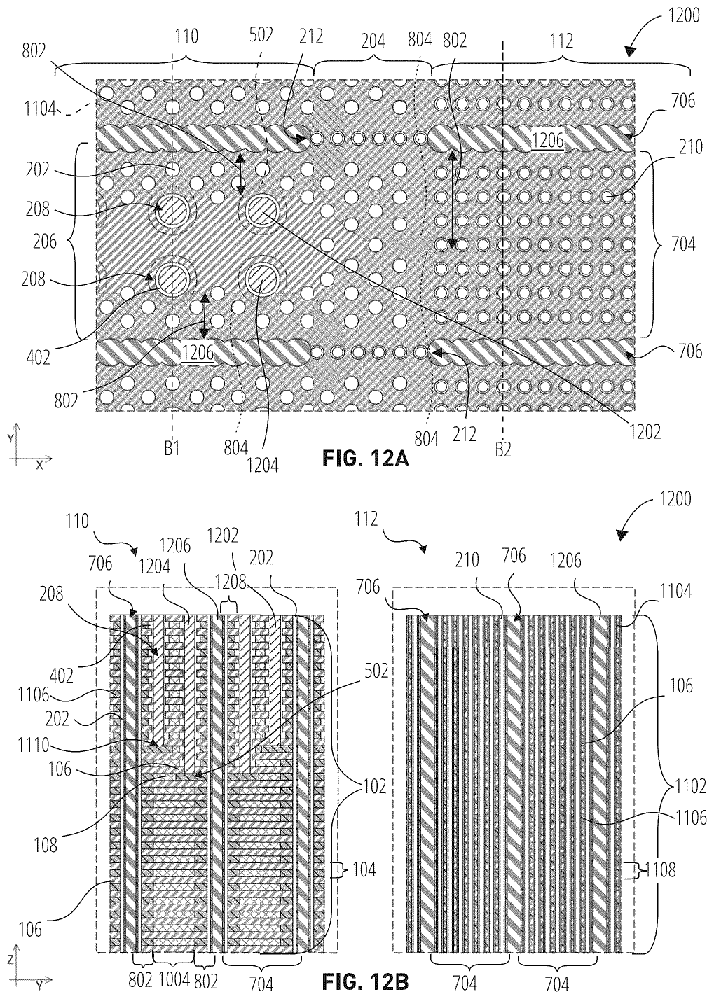

The plugs 602 may be removed (e.g., etched) to reopen the WL contact openings 208, and additional conductive material(s) 1202 may be formed in the WL contact openings 208 to form the WL contacts 1204, illustrated in FIG. 12A and FIG. 12B. Each WL contact 1204 extends to a target conductive level (e.g., a target WL) of the stack 1102; that is, to a target conductive structure 1106 of the stack 1102, which is the conductive structure 1106 providing the landing area 1110 for the WL contact 1204.

The WL contacts 1204 may be formed of and include one or more additional conductive material(s) 1202, such as one or more of: at least one metal (e.g., one or more of tungsten, titanium, nickel, platinum, rhodium, ruthenium, iridium, aluminum, copper, molybdenum, silver, gold), at least one alloy (e.g., an alloy of one or more of the aforementioned metals), at least one metal-containing material that includes one or more of the aforementioned metals (e.g., metal nitrides, metal silicides, metal carbides, metal oxides, such as a material including one or more of titanium nitride (TiN), tantalum nitride (TaN), tungsten nitride (WN), titanium aluminum nitride (TiAlN), iridium oxide (IrOₓ), ruthenium oxide (RuOₓ), alloys thereof), at least one conductively-doped semiconductor material (e.g., conductively-doped silicon, conductively-doped germanium, conductively-doped silicon germanium, conductive-doped polysilicon), and at least one other material exhibiting electrical conductivity.

Once formed, the WL contact 1204 includes its additional conductive material(s) 1202 extending vertically through a partial height of the stack 1102 to a target WL level of a target tier 1108; that is, to a target elevation of conductive structure 1106 of the stack 1102. The WL contact 1204 includes the additional conductive material(s) 1202 horizontally surrounded—in elevations above the lowest insulative structure 106 through which the additional conductive material(s) 1202 extend—by the liner structure 402. Proximate the base of the WL contact 1204, the additional conductive material(s) 1202 contact (directly contact) the conductive material(s) 1104 that were formed in the base (e.g., the expanded base 502) of the WL contact opening 208 to provide the landing area 1110. The additional conductive material(s) 1202 of the WL contact 1204 may extend through (e.g., and be in direct physical contact with) the insulative structure 106 that is immediately above the landing area 1110.

One or more non-conductive fill material(s) may be formed (e.g., deposited) in the inter-block openings 706 to form inter-block structures 1206. Each inter-block structure 1206 may extend between longitudinally neighboring (Y-direction) blocks 704 in at least the WL-contact area 110 and the array area 112.

To electrically isolate the conductive structures 1106 of one of the blocks 704 from the conductive structures 1106 of the neighboring block 704, one or more additional electrically-insulative inter-block structures may also be formed through the intermediate area 204. For example, when forming the inter-block openings 706 in the array area 112 and the WL-contact area 110, adjacent inter-block pillars 212 of the intermediate area 204 may also be removed and merged into the elongate openings that form the inter-block openings 706. As another example, one or more other non-conductive (e.g., electrically insulative) features may be formed in the intermediate area 204 at this or previous stages, extending horizontally through the intermediate area 204 to connect with the inter-block openings 706 of the WL-contact area 110 and the array area 112, respectively.

In some embodiments, each inter-block structure 1206 includes at least one non-conductive material (e.g., non-conductive silicon and/or insulative material(s)) lined by one or more other non-conductive material(s) (e.g., other insulative material(s)).

Formed, then, is a microelectronic device structure 1200 that includes the WL contacts 1204 extending through the WL-contact area 110 of the stack 1102 (including through or along areas 1004 of the stack 1102 that continue to have the parsac structures 108 of the precursor stack 102) to target levels of the stack 1102 that are partially conductive structure 1106 (e.g., in the array area 112 and in part of the WL-contact area 110) and partially parsac structure 108 (e.g., non-conductive structure, e.g., insulative structure) (e.g., in part of the WL-contact area 110).

Between neighboring WL contacts 1204 of the block 704 (e.g., in the area 1004), the stack 1102 includes remnants of the precursor stack 102, including its vertically repeated tiers 104 that are substantially free of conductive material (e.g., the insulative structures 106 and the parsac structures 108). This area 1004 of the device may also be substantially free of supports 202, though the disclosure is not so limited.

Between the WL contacts 1204 and sidewalls of the block 704 (e.g., adjacent the inter-block structures 1206), the stack 1102 includes the vertically repeated tiers 1108 that include conductive material (e.g., the tiers 1108 having the insulative structures 106 and the conductive structures 1106). These areas (in distances 802 and throughout scope 804) provide the “bridges” discussed above, such that each conductive structure 1106 includes a conductive rail 1208 along its sidewall (e.g., adjacent the 1206). In the elevations above the target conductive structure 1106 (i.e., the conductive structure 1106 providing the landing area 1110 for a target word line (e.g., access line)), the conductive rails 1208 extend to and partially around the liner structures 402. In the elevation of the target conductive structure 1106, the conductive rail 1208 extends to and through the extended expanded base 502, and so may be the longest (Y-direction) conductive rail 1208 of the stack 1102. In elevations below the target conductive structure 1106, the conductive rails 1208 to an area that is at least partially overlapped by the landing area 1110. The conductive rails 1208 provide continuity of each respective conductive structure 1106 throughout a width (X-direction) of the block 704 at each respective conductive structure 1106 level of the stack 1102.

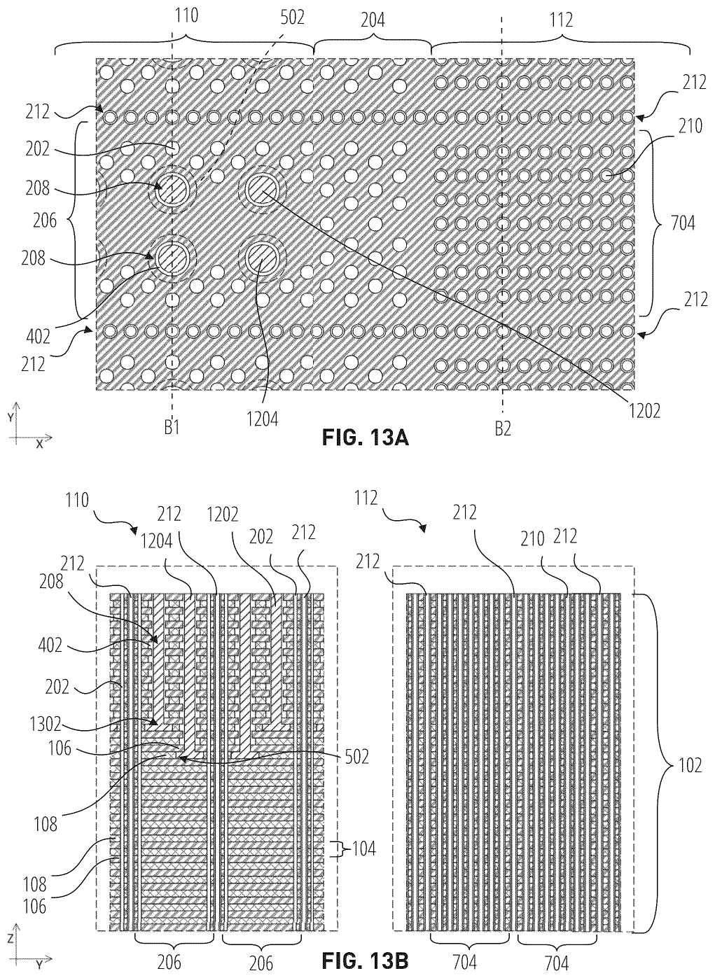

At least in embodiments according to the illustrations of FIG. 1 through FIG. 12B, the formation of the additional conductive material(s) 1202 to form the WL contacts 1204 is a stage subsequent to stage(s) of the full exhumation of the parsac structures 108 from the array area 112, the partial exhumation of the parsac structures 108 from the WL-contact area 110, and the formation of the conductive material(s) 1104 to form the conductive structures 1106 in the array area 112 and the WL-contact area 110. In other embodiments, such as, for example, the process(es) illustrated in FIG. 13A through FIG. 17B, the WL contacts 1204 may be formed before the processes that include the full and partial exhumations and the conductive structures 1106 formation.

Also, while embodiments according to the illustrations of FIG. 1 through FIG. 12B include forming the additional conductive material(s) 1202 of the conductive structures 1106 substantially concurrently in both the WL-contact area 110 and the array area 112, in other embodiments—such as, for example, the process(es) illustrated in FIG. 13A through FIG. 17B—the conductive structures 1106 may be formed (and the full and partial exhumation processes may be performed) in one of the areas (e.g., the WL-contact area 110 or the array area 112) before another of the areas (e.g., the other of the WL-contact area 110 or the array area 112).

With reference to FIG. 13A through FIG. 17B, illustrated are various stages of a method of forming a microelectronic device (e.g., a memory device, such as a 3D NAND Flash memory device), in accordance with additional embodiments of the disclosure. The stage(s) illustrated in FIG. 13A and FIG. 13B may follow the stage illustrated in FIG. 5A and FIG. 5B, described above. Accordingly, the illustrated process stage(s) of FIG. 13A and FIG. 13B may follow formation of the liner structures 402 and, in some embodiments, the formation of the expanded bases 502 in the WL contact openings 208; additionally, the precursor stack 102 may remain at this stage with the parsac structures 108 in both the array area 112 and the WL-contact area 110, as well as in the intermediate area 204.

After forming the WL contact openings 208 (FIG. 4A and FIG. 4B) and, optionally, forming the expanded bases 502 (FIG. 5A and FIG. 5B), the additional conductive material(s) 1202 may be formed in the WL contact openings 208 and the expanded bases 502 to form the WL contacts 1204, as illustrated in FIG. 13A and FIG. 13B. Formation of the plugs 602 (FIG. 6A and FIG. 6B) may be omitted in this embodiment. The resulting WL contacts 1204 individually include an expanded base portion of the additional conductive material(s) 1202 (in the area of the expanded base 502 of the WL contact openings 208) that is integral with the additional conductive material(s) 1202 of the remainder of the WL contact 1204, providing an integrated landing area 1302 that may function in substantially the same manner as the landing area 1110 (FIG. 11A and FIG. 11B) of the embodiment(s) described above. The additional conductive material(s) 1202 of the WL contact 1204 are, thus, in direct contact (e.g., along sidewall(s)) with a parsac structure 108 that partially, horizontally surrounds the expanded base 502. One of the insulative structures 106 is directly below the additional conductive material(s) 1202 of the WL contact 1204.

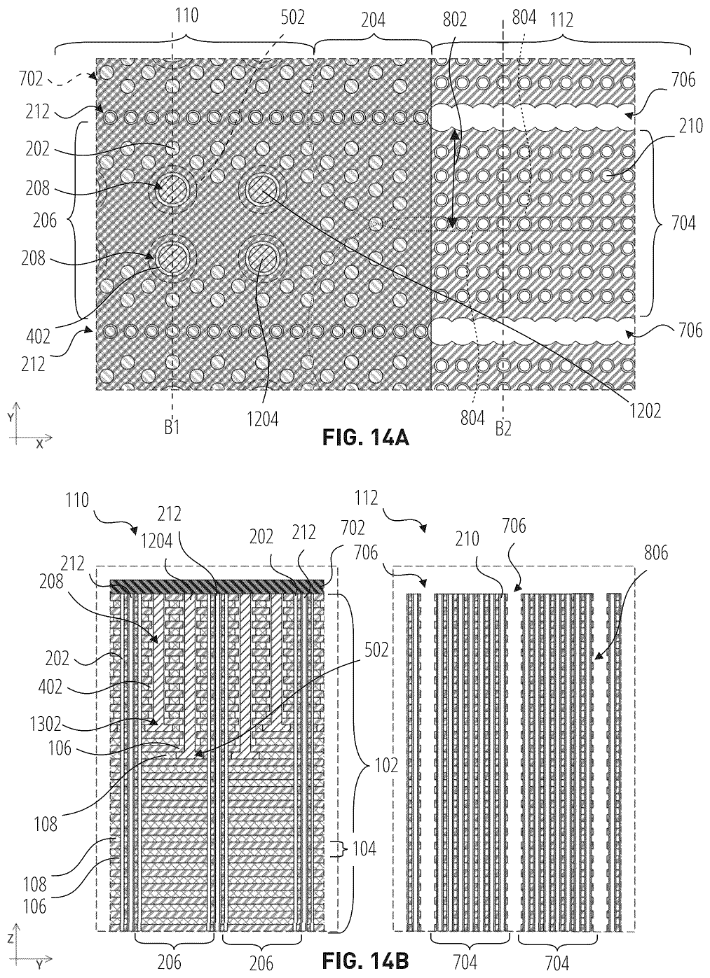

With reference to FIG. 14A and FIG. 14B, the mask structure 702 may be formed over the WL-contact area 110 and, in some embodiments, over all or part of the intermediate area 204, leaving the array area 112 exposed, e.g., in a manner described above with regard to FIG. 7A and FIG. 7B.

The inter-block pillars 212 of the array area 112 may then be removed and adjacent insulative structures 106 may be recessed to form the inter-block openings 706 in the array area 112, e.g., in a manner described above with regard to FIG. 7A and FIG. 7B.

Via the inter-block openings 706, the full exhumation process may be performed throughout the array area 112, e.g., in a manner described above with regard to FIG. 8A and FIG. 8B.

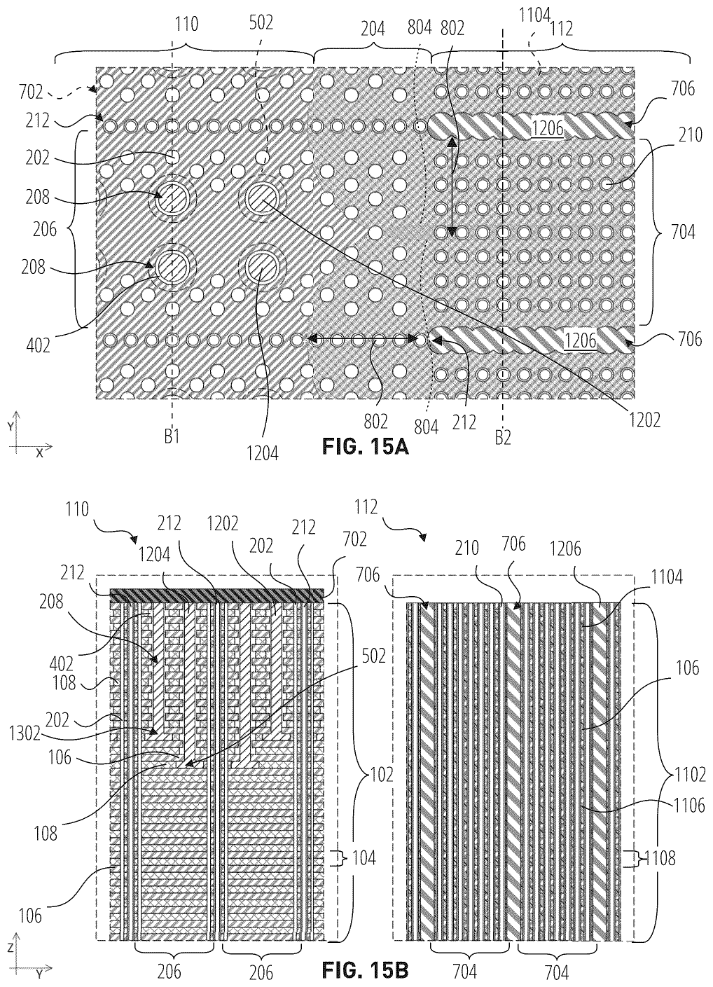

Then, with reference to FIG. 15A and FIG. 15B, the conductive structures 1106 may be formed in the array area 112, throughout the scope 804 of the full exhumation, to form the stack 1102 and its tiers 1108 through the array area 112, e.g., in a manner described above with regard to FIG. 11A and FIG. 11B, except without yet forming the conductive structures 1106 in the WL-contact area 110.

The inter-block structures 1206 may be formed to substantially fill the inter-block openings 706 in the array area 112, e.g., in a manner described above with regard to FIG. 12A and FIG. 12B, though without yet forming the inter-block structures 1206 of the WL-contact area 110.

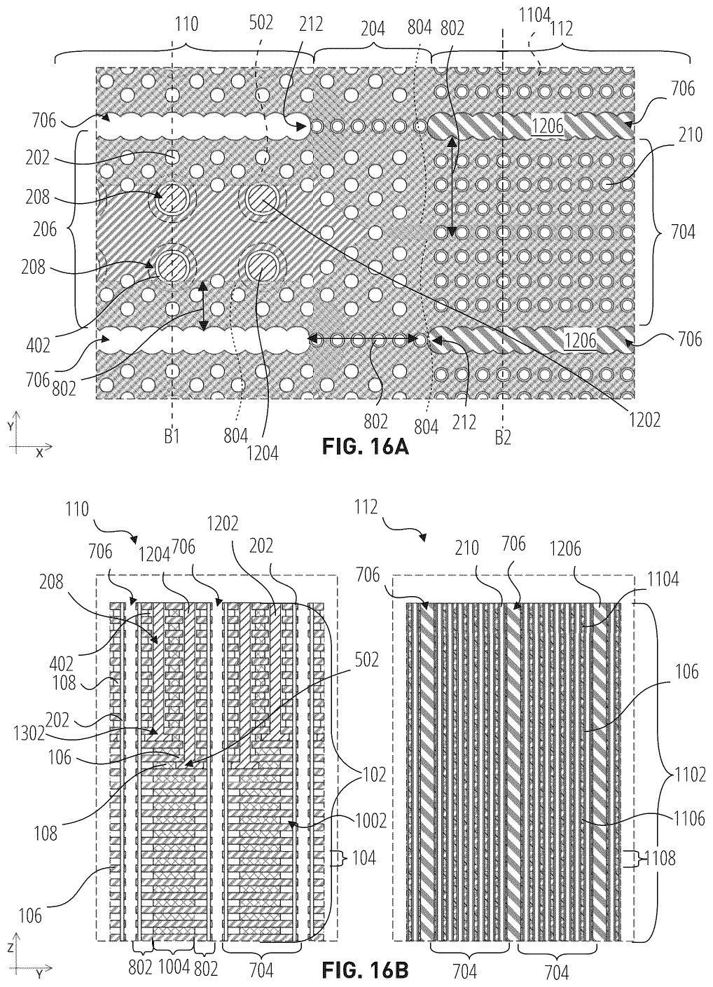

With reference to FIG. 16A and FIG. 16B, in some embodiments, after forming the conductive structures 1106 in the array area 112, the inter-block openings 706 of the WL-contact area 110 are formed, e.g., in a manner described above with regard to FIG. 9A and FIG. 9B, and the partial exhumation is carried out in the WL-contact area 110, e.g., in a manner described above with regard to FIG. 9A and FIG. 9B, except that the presence of the already-formed WL contacts 1204 effectively encloses the WL contact openings 208, rather than forming and using plugs 602 (FIG. 6A and FIG. 6B) for this purpose. The partial exhumation, according to the present embodiment, is tailored (e.g., in duration and/or etchant chemistry) to at least reach and expose a sidewall of the WL contacts 1204 at the base (e.g., the expanded base 502) of the WL contact openings 208. The additional voids 1002 may reach and communicate to only the sidewall at the base (e.g., the expanded base 502) of the WL contact openings 208 because the liner structures 402 and the insulative structures 106 above the base level separate the higher-elevation additional voids 1002 from the other portions of the WL contacts 1204.

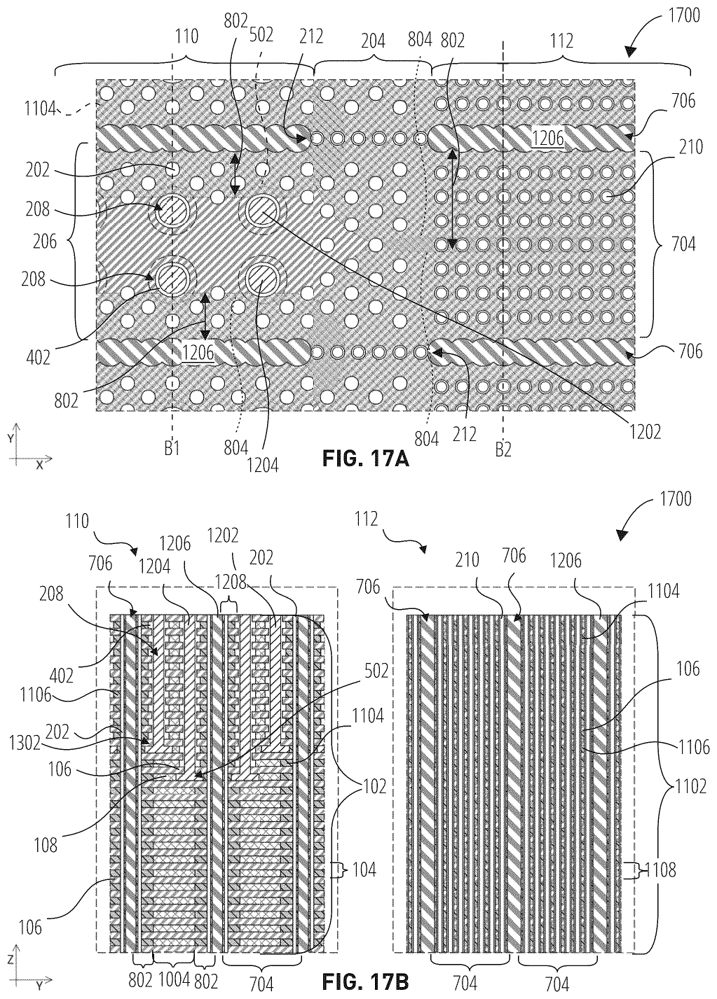

After the partial exhumation, the conductive material(s) 1104 may be formed in the additional voids 1002 (FIG. 16B)—as illustrated in FIG. 17A and FIG. 17B—to form the conductive structures 1106 horizontally between the area 1004 the inter-block openings 706 and the remnant parsac structures 108. The inter-block structures 1206 may be formed, e.g., in a manner described above with regard to FIG. 12A and FIG. 12B. In some embodiments in which the intermediate area 204 does not yet include electrically insulating features between neighboring (X-direction) inter-block structures 1206, such electrically insulating features may be formed at this or prior stages. Thus, the blocks 704 are defined and the conductive structures 1106 of one block 704 are electrically isolated from the conductive structures 1106 of a neighboring block 704. For each target WL level (e.g., each target conductive structure 1106), the conductive structure 1106 may be in direct physical contact with a sidewall of the additional conductive material(s) 1202 of the WL contact 1204. The conductive rails 1208 at levels above and below the integrated landing area 1302 may at least partially vertically overlap or underlap, respectively, an area of the integrated landing area 1302.

A resulting microelectronic device structure 1700 may have structures and materials that are substantially the same as the structures and materials of the microelectronic device structure 1200 of FIG. 12A and FIG. 12B, except that the WL contacts 1204 have a differently shaped base and except that the WL contacts 1204 connect to their target conductive structures 1106 (e.g., of the target WL elevations) along a sidewall at the base of the WL contacts 1204. For example, the WL contact 1204 may have a substantially inverted “T” shape, with the base of the WL contact 1204 providing the integrated landing area 1302 that physically connects with the conductive structure 1106 of the target word line (WL) level along abutting sidewalls, rather than along abutting horizontal surfaces as in the microelectronic device structure 1200 of FIG. 12A and FIG. 12B. Notably, the top plan view of the microelectronic device structure 1700 illustrated in FIG. 17A is substantially identical to the top plan view of the microelectronic device structure 1200 illustrated in FIG. 12A.

In some embodiments, such as those described above with regard to FIG. 1 through FIG. 17B, the base of the WL contact openings 208 is expanded to form the expanded bases 502 prior to forming the WL contacts 1204. In other embodiments, the base of the WL contact openings 208 is not expanded. In such embodiments, the method of formation may omit the stage illustrated in FIG. 5A and FIG. 5B and discussed above with to FIG. 1 through FIG. 12B, and/or with regard to FIG. 13A through FIG. 17B.

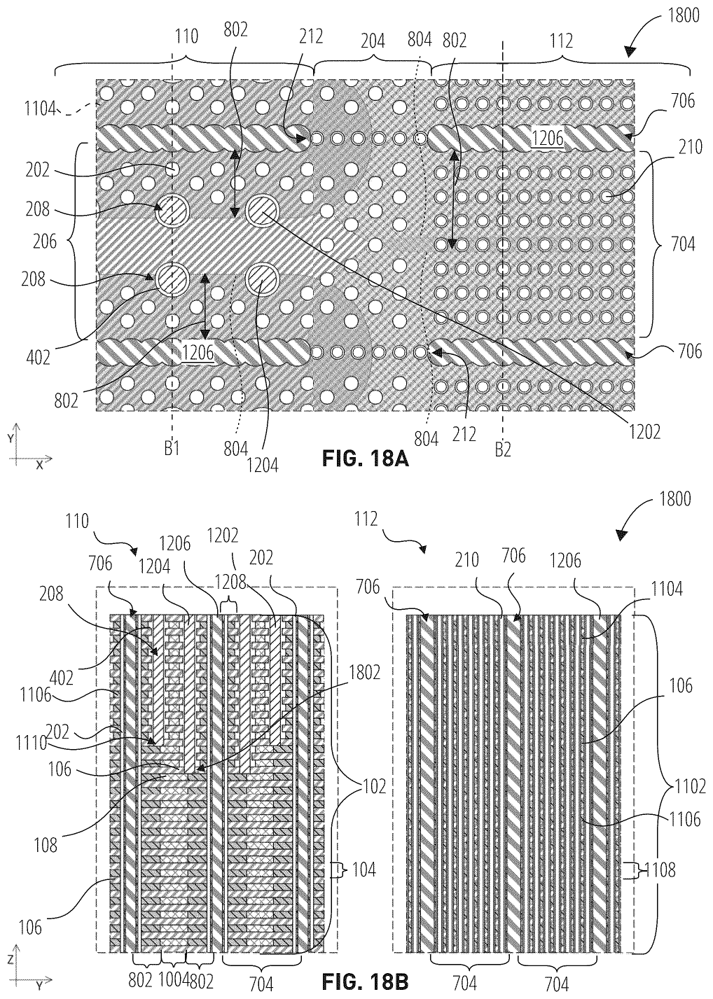

For example, after forming the WL contact openings 208 as illustrated in FIG. 4A and FIG. 4B, the method may proceed to the stage(s) described above with regard to FIG. 6A through FIG. 12B. This method may form a microelectronic device structure 1800 such as that illustrated in FIG. 18A and FIG. 18B. In such method, the partial exhumation in the WL-contact area 110 (e.g., illustrated in FIG. 9A and FIG. 9B) may be tailored so that the additional voids 1002 communicate to not-extended bases 1802 of the WL contact openings 208 (e.g., at a lower end, or a portion of a lower end, of the not-extended bases 1802 of the WL contact openings 208). Therefore, the partial exhumation—and the subsequently-formed conductive structures 1106—may extend a relatively longer distance 802 from the inter-block openings 706 to contact the not-extended bases 1802, compared to the distance 802 of the partial exhumation distance 802 in the stage illustrated in FIG. 9A and FIG. 9B by which the distance 802 reached the expanded bases 502 of the WL contact openings 208.

The conductive structures 1106 in elevations from the landing area 1110 and lower in the stack 1102 may extend at least somewhat horizontally beyond the proximal side of the liner structure 402 so that a sufficient area of the target conductive structure 1106 provides the landing area 1110 for physical and electrical contact with the additional conductive material(s) 1202 of the WL contact 1204.

As in the above-described embodiments, a resulting microelectronic device structure 1800 includes through-stack WL contacts 1204 extending to target levels of the stack that are partially conductive (e.g., with the conductive structures 1106 extending the distance 802 from the inter-block structures 1206) and partially non-conductive (e.g., with remnants of the parsac structures 108 in the area 1004 between the conductive structures 1106 and between horizontally neighboring WL contacts 1204 of the block 704).

Any embodiment described herein as including formation of the expanded base 502 may likewise be modified to omit the base expansion, and the partial exhumation may be likewise modified to provide a sufficient landing area 1110 between the not-extended bases 1802 of the WL contacts 1204 and the target conductive structure 1106 level (e.g., the target WL level) of the stack 1102.

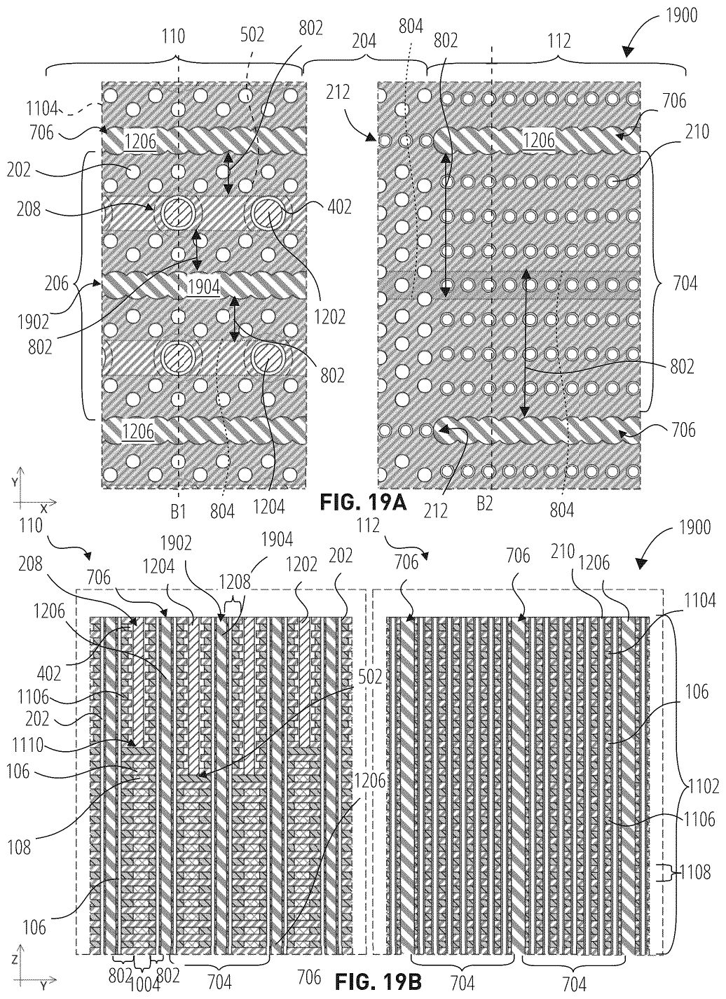

In some embodiments, one or more additional openings substantially like the inter-block openings 706 may be formed within the block 704 in the WL-contact area 110, so as to increase the access for the partial exhumation process and formation of the conductive material(s) 1104 (and the conductive structures 1106). For example, with reference to FIG. 19A and FIG. 19B, an intra-block opening 1902 may be formed (e.g., by removing a row of inter-block pillars 212 and recessing surrounding insulative structures 106) within (e.g., central to) the block area 206 in the WL-contact area 110, in a region horizontally (Y-direction) between neighboring WL contacts 1204 of the block 704. The intra-block openings 1902 may be formed only in the WL-contact area 110 of a microelectronic device structure 1900, such that it may not align with, and may not connect to, an inter-block opening 706 in the array area 112 and/or may not align with another row of remaining inter-block pillars 212 in the intermediate area 204.

The microelectronic device structure 1900 includes double conductive rails 1208 along each row of WL contacts 1204. That is, one conductive rail 1208 may be disposed to a first horizontal (Y-direction) side of each WL contact 1204 and a second conductive rail 1208 may be disposed to a second horizontal (Y-direction) side of each WL contact 1204. In contrast, the microelectronic device structure 1200 of FIG. 12A and FIG. 12B, the microelectronic device structure 1700 of FIG. 17A and FIG. 17B, and the microelectronic device structure 1800 of FIG. 18A and FIG. 18B each include, in the WL-contact area 110, one conductive rail 1208 to one lateral side of each row of WL contacts 1204, and the other lateral side of the row of WL contacts 1204 is directly adjacent the area 1004 that retains the precursor stack 102 materials (including the remnants of the parsac structures 108). The double conductive rails 1208 per row of WL contacts 1204 may facilitate electrical communication between the word lines (e.g., access lines) (provided by the conductive structures 1106) and the WL contacts 1204.

In embodiments in which the base of the WL contact openings 208 are expanded (e.g., such as in a manner described above with regard to FIG. 5A and FIG. 5B, to form the expanded bases 502), the partial exhumation of the parsac structures 108 may be tailored to form the additional voids 1002 (FIG. 9B) to communicate with both horizontal sides of the expanded base 502. For example, one of the additional voids 1002 (e.g., extending from one of the inter-block openings 706) may communicate to the left side (Y-direction) of the expanded base 502, and another of the additional voids 1002 (e.g., extending from one of the intra-block openings 1902) may communicate to the right side (Y-direction) of the expanded base 502. The expanded bases 502 may then be filled with the additional conductive material(s) 1202 from either or both sides of the expanded base 502. In the resulting landing area 1110, the additional conductive material(s) 1202 of the target conductive structure 1106 may extend substantially continuously from one inter-block opening 706 to a neighboring intra-block opening 1902, and vice versa, as illustrated in FIG. 19B.

In some embodiments consistent with the microelectronic device structure 1900 of FIG. 19A and FIG. 19B, the parsac structures 108 may be wholly removed and replaced with conductive structures 1106 in the levels of the stack 1102 that are between neighboring WL contacts 1204 of an individual block 704. The levels with portions retaining the precursor stack 102 structure (e.g., including parsac structure 108 remnants) may be levels below the target WL levels (e.g., levels below a respective landing area 1110).

The intra-block opening 1902 may be formed (e.g., etched through the precursor stack 102) before, during, or after forming the inter-block openings 706, e.g., in the manner described above with regard to FIG. 9A and FIG. 9B and/or with regard to FIG. 16A and FIG. 16B.

Intra-block structures 1904 may be formed in the intra-block openings 1902 in substantially the same manner described above with regard to forming the inter-block structures 1206 in the inter-block openings 706, e.g., in a manner described above with regard to FIG. 12A and FIG. 12B and/or with regard to FIG. 17A and FIG. 17B. However, the intra-block structures 1904 may not electrically isolate longitudinally neighboring (Y-direction) portions of the conductive structures 1106, e.g., due to conductive material(s) in the horizontally adjacent (X-direction) portion of the block 704 (i.e., in the array area 112 and, in some embodiments, also the intermediate area 204).

To accommodate room for the intra-block openings 1902 and the intra-block structures 1904, the block areas 206 and resulting blocks 704 may be relatively longer (Y-direction) than block areas 206 and blocks 704 of embodiments described above. In some such embodiments, supports 202 are included between the intra-block structures 1904 and the neighboring rows of the WL contacts 1204, as illustrated in FIG. 19A. In other embodiments, no supports 202 are included between the intra-block structures 1904 and the neighboring rows of the WL contacts 1204.

As in the above-described embodiments, the resulting microelectronic device structure 1900 includes through-stack WL contacts 1204 extending to target levels of the stack 1102 that are partially conductive (e.g., with the conductive structures 1106 extending the distance 802 from the inter-block structures 1206 and from the intra-block structures 1904) and partially non-conductive (e.g., with remnants of the parsac structures 108 in the area 1004 between the conductive structures 1106).

In accordance with the embodiments described above with regard to FIG. 1 through FIG. 19B, each block 704 includes two rows (X-direction) of WL contacts 1204, and one inter-block opening 706 (or row of inter-block openings 706) may be formed along each respective lateral side (extending in the X-direction) of each block 704. Having one inter-block opening 706 (or row of inter-block openings 706) along each respective side (extending in X-direction) of the block 704 enables the conductive structures 1106 to be formed so that each conductive rail 1208 (e.g., each bridge) of the conductive structure 1106 extends horizontally (Y-direction) from one of the inter-block openings 706 to a respective one of two rows of WL contacts 1204.

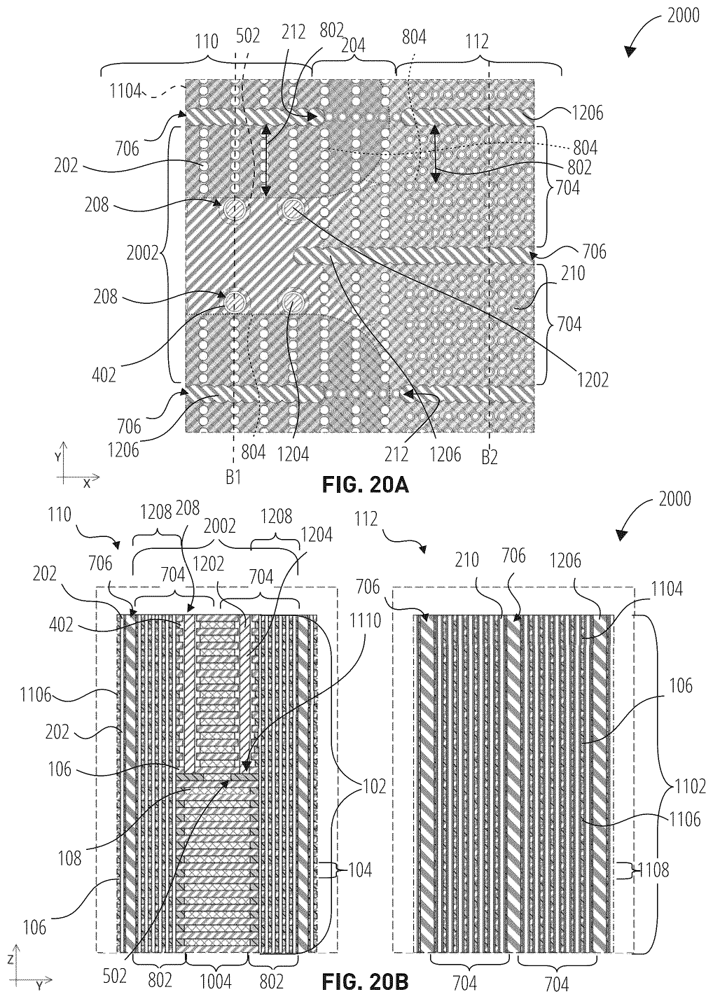

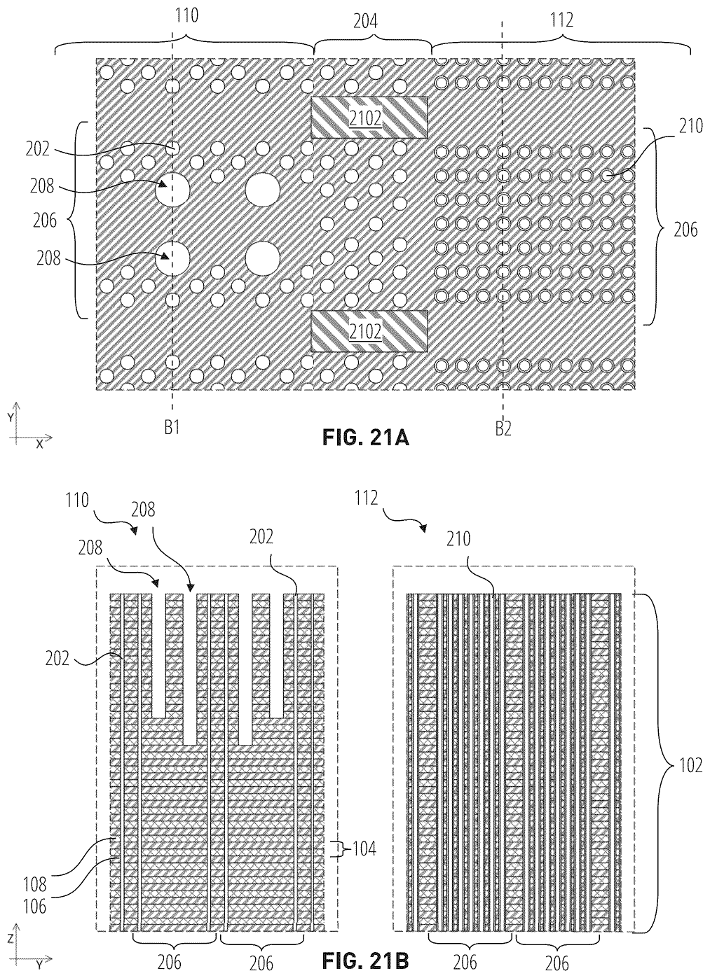

In other embodiments, each block 704 may include only a single row of the WL contacts 1204, and only one lateral side of each block 704 (e.g., in the WL-contact area 110 thereof) may be adjacent (e.g., defined by) one inter-block opening 706, such as illustrated in FIG. 20A and FIG. 20B, or adjacent one row of inter-block openings 706. A pair of the inter-block openings 706 (or a pair of rows of inter-block openings 706) (and resulting inter-block structures 1206) thus divides the stack into dual blocks 2002 groupings.

In each dual block 2002 grouping, the blocks 704—and the conductive structures 1106 thereof—may be electrically isolated from one another by the area 1004 with the structure of the precursor stack 102 and by one of the inter-block structures 1206 of the array area 112 extending to or into the area 1004 of the WL-contact area 110 of the device, as illustrated in FIG. 20A. Thus, in the area between neighboring blocks 704 of the dual block 2002, the stack may be substantially free of conductive material(s). In the array area 112 and, optionally, some or all of the intermediate area 204, the between-block area may be free of conductive material(s) due to the inter-block structure 1206 formed in one of the inter-block openings 706. In the WL-contact area 110 and, optionally, some or all of the intermediate area 204, the between-block area may be free of conductive material(s) due to the area 1004 that retains the precursor stack 102 material(s) (e.g., a stack of non-conductive structures, including the insulative structures 106 and remnants of the parsac structures 108). In such embodiments, the between-block inter-block structure 1206 (e.g., in one of the inter-block openings 706) of the array area 112 may align (X-direction) with the area 1004 (e.g., retaining the parsac structures 108) of the WL-contact area 110.

As in the above-described embodiments, a resulting microelectronic device structure 2000 includes through-stack WL contacts 1204 extending to target levels of the stack 1102 that are partially conductive (e.g., with the conductive structures 1106 extending the distance 802 from the inter-block structures 1206) and partially non-conductive (e.g., with remnants of the parsac structures 108 in the area 1004 between the blocks 704 and between the horizontally neighboring WL contacts 1204).

Because longitudinally neighboring (Y-direction) WL contacts 1204 of the dual block 2002 are each associated with a different block 704 of the dual block 2002 grouping, the longitudinally neighboring (Y-direction) WL contacts 1204 may both extend to a same target level of the stack 1102. Within a respective one of the blocks 704 of the dual block 2002, laterally neighboring WL contacts 1204 may be formed to extend to different target levels of the stack 1102.

With reference to FIG. 21A through FIG. 24B, illustrated are various stages of a method of forming a microelectronic device (e.g., a memory device, such as a 3D NAND Flash memory device), in accordance with additional embodiments of the disclosure. The stage(s) illustrated in FIG. 21A and FIG. 21B may follow the stage illustrated in FIG. 1, described above. The supports 202, WL contact openings 208, and pillars 210 may be formed, e.g., in the manner described above with regard to FIG. 2A and FIG. 2B.

Rather than forming the inter-block pillars 212 (FIG. 2A and FIG. 2B) in the inter-block areas, an intermediate inter-block structure 2102 may be formed in the intermediate area 204 of each inter-block area. For example, an opening (e.g., slit) may be formed through the precursor stack 102 to extend the width (X-direction) of the intermediate area 204 and to or into the adjacent WL-contact area 110 and array area 112. Non-conductive (e.g., insulative) material(s) may be formed in such opening (e.g., slit) to form the intermediate inter-block structure 2102. The non-conductive material(s) may be any of the non-conductive material(s) from which the inter-block structures 1206 (FIG. 12A and FIG. 12B) may be formed. Accordingly, in some embodiments, the intermediate inter-block structures 2102 are formed of an include substantially the same material(s) as the inter-block structures 1206. In other embodiments, the intermediate inter-block structures 2102 are formed of and include different non-conductive (e.g., insulative) material(s) than the inter-block structures 1206.

The fabrication process may continue in a manner described above with regard to any of the above-described figures, except that stages described above as forming the inter-block openings 706 by removal of inter-block pillars 212 and recessing of surrounding insulative structures 106 to formed merged inter-block openings 706 (e.g., with scalloped sidewalls) may instead be formed by forming elongate inter-block openings 706 (e.g., with substantially planar sidewalls).

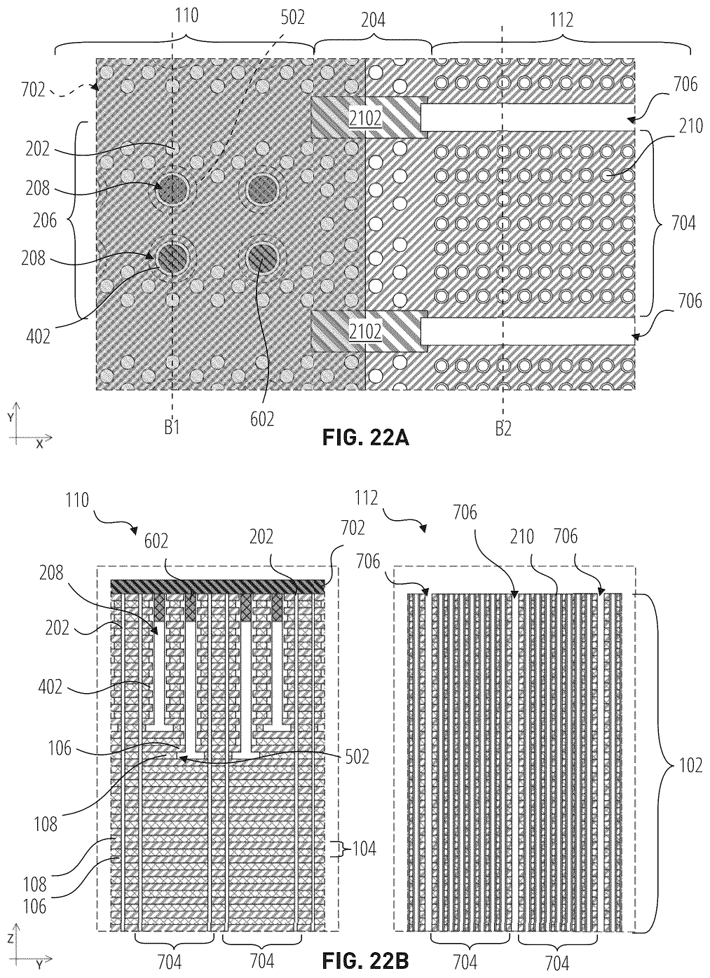

For example, with reference to FIG. 22A and FIG. 22B, the inter-block openings 706 of the array area 112 may be formed as elongate slits rather than by the processes described above with regard to FIG. 7A and FIG. 7B.

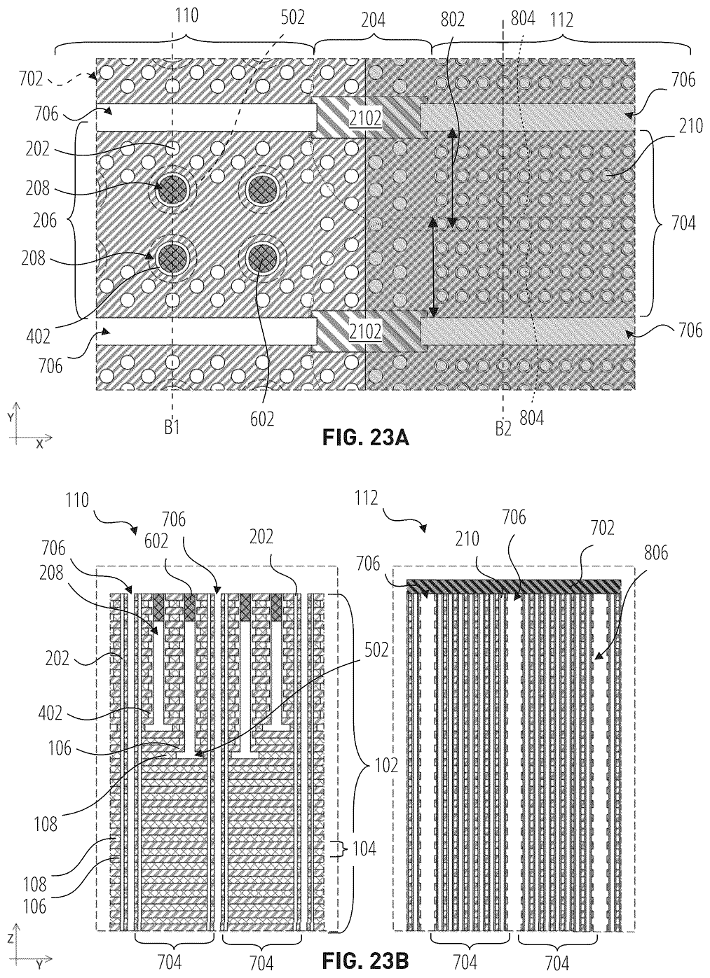

In continuance of this example, and with reference to FIG. 23A and FIG. 23B, the inter-block openings 706 of the WL-contact area 110 may be formed as elongate slits rather than by the processes described above with regard to FIG. 9A and FIG. 9B.

The inter-block openings 706 of the array area 112 and the WL-contact area 110 may be formed to connect to, and may be formed to extend partially into, the intermediate inter-block structures 2102 in the intermediate area 204.

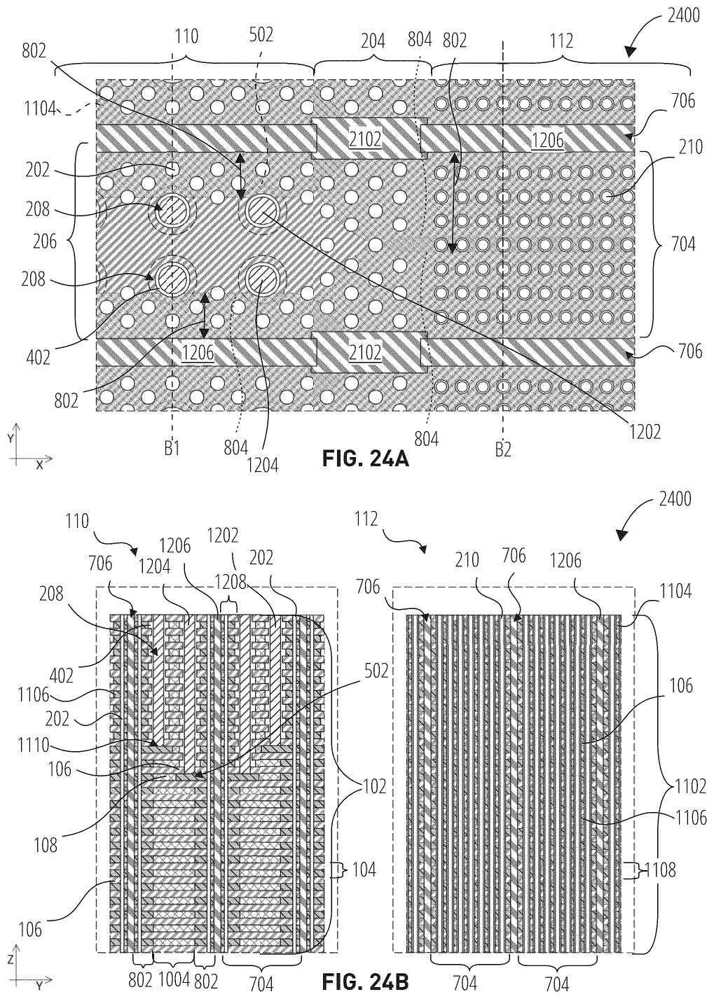

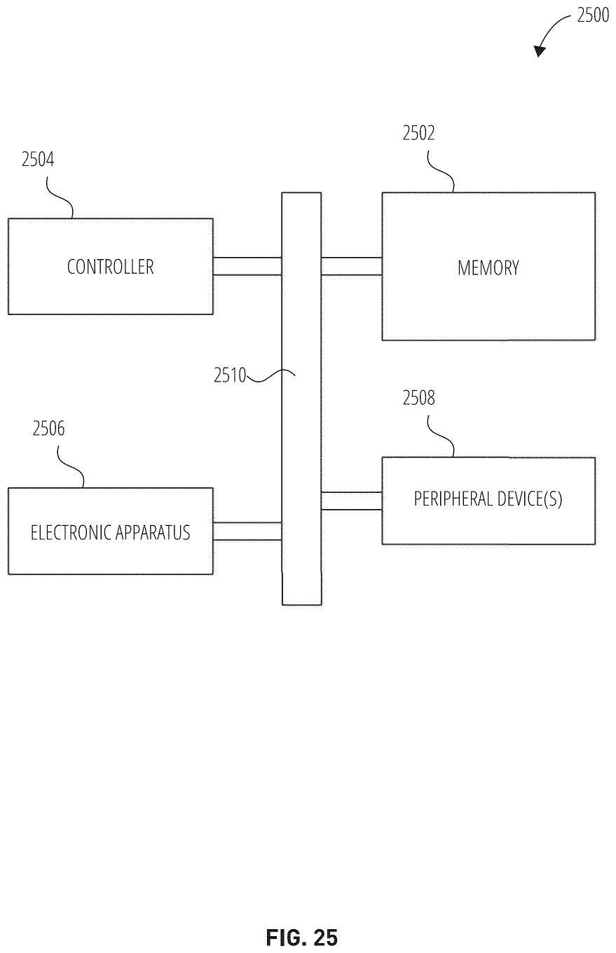

With reference to FIG. 24A and FIG. 24B, the inter-block structures 1206 may be formed in the inter-block openings 706, e.g., in a manner described above with regard to FIG. 12A and FIG. 12B.

Though FIG. 21A and FIG. 2B illustrate the intermediate inter-block structures 2102 as being formed before the inter-block openings 706 and inter-block structures 1206 are formed, as well as before the full exhumation, partial exhumation, and conductive-structure formation stages, in other embodiments, the intermediate inter-block structures 2102 may be formed after these stages have been completed.

As in the above-described embodiments, a resulting microelectronic device structure 2400 includes through-stack WL contacts 1204 extending to target levels of the stack that are partially conductive (e.g., with the conductive structures 1106 extending the distance 802 from the inter-block structures 1206) and partially non-conductive (e.g., with remnants of the parsac structures 108 in the area 1004 between the conductive structures 1106 and between horizontally neighboring WL contacts 1204 of the block 704). In the microelectronic device structure 2400, the blocks 704 are defined by inter-block structures 1206 and intermediate inter-block structures 2102.

Any embodiment described herein as including formation of inter-block pillars 212 in the intermediate area 204 may be modified to omit the inter-block pillars 212 in the intermediate area 204 and to instead form the intermediate inter-block structures 2102 in the intermediate area 204. The stack may thus be divided into the blocks 704 by virtue of the inter-block structures 1206 and the intermediate inter-block structures 2102.

It should be understood that the quantity of tiers in the stack (e.g., the tiers 104 in the precursor stack 102, the tiers 1108 in the stack 1102) may be other than the quantity illustrated in the figures without departing from the disclosure. The quantity of tiers may range, for example, from thirty-two to three-hundred or more. The tiers may be arranged in one or more decks.

Accordingly, disclosed is a method for forming a microelectronic device. The method comprises forming a precursor stack comprising a vertically repeated sequence of tiers respectively comprising an insulative structure and a partially sacrificial structure. An array of pillars is formed, and the pillars extend substantially vertically through a height of the precursor stack in an area are of the stack. Contact openings are formed to extend to various depths of the precursor stack in an additional area of the stack horizontally adjacent the array area. In the array area of the stack, the partially sacrificial structures are substantially wholly removed to form voids between the insulative structures, and conductive structures are formed in the voids. In the additional area of the stack, the partially sacrificial structures are partially removed to form additional voids. At least some of the additional voids communicate with the contact openings at respective bases of the contact openings. Additional conductive structures are formed in the additional voids. Conductive contacts are formed in the contact openings and in physical contact with the additional conductive structures at the respective bases of the contact openings.

Also accordingly, disclosed is a microelectronic device comprising a stack structure divided into blocks. The stack structure comprises a vertically repeated sequence of tiers respectively comprising at least one level with an insulative structure. The tiers also respectively comprise at least one other level with a conductive structure and with at least one non-conductive structure. An array of pillars extends substantially vertically through a height of the stack structure in a first area of the stack structure. In the first area, the tiers comprise the insulative structures and the conductive structures and do not comprise the non-conductive structures. Conductive contacts extend substantially vertically to various depths of the stack structure in a second area of the stack structure horizontally adjacent the first area. In the second area, the tiers comprise the insulative structures and both the conductive structures and the non-conductive structures.

Also accordingly, disclosed is a microelectronic device comprising a pillar array comprising pillars extending substantially vertically through a stack structure in an array area. Conductive contacts extend various heights through the stack structure in a contact area horizontally adjacent the array area. In the array area, the stack structure comprises a vertically repeated tier sequence respectively comprising at least one insulative structure and at least one conductive structure. In the contact area, the stack structure comprises—to at least one horizontal side of a respective one of the conductive contacts—the vertically repeated tier sequence respectively comprising the at least one insulative structure and the at least one conductive structure. Also in the contact area, the stack structure comprises—in levels of the stack structure below the respective one of the conductive contacts, an additional vertically repeated tier sequence respectively comprising the at least one insulative structure and at least one non-conductive structure.

FIG. 25 shows a block diagram of a system 2500, according to embodiments of the disclosure, which system 2500 includes memory 2502 including arrays of vertical strings of memory cells adjacent microelectronic device structure(s) (e.g., the microelectronic device structure 1200 of FIG. 12A and FIG. 12B, the microelectronic device structure 1700 of FIG. 17A and FIG. 17B, the microelectronic device structure 1800 of FIG. 18A and FIG. 18B, the microelectronic device structure 1900 of FIG. 19A and FIG. 19B, the microelectronic device structure 2000 of FIG. 20A and FIG. 20B, and/or the microelectronic device structure 2400 of FIG. 24A and FIG. 24B, respectively). Therefore, the architecture and structure of the memory 2502 may include one or more device structures according to embodiments of the disclosure and may be fabricated according to one or more of the methods described above (e.g., with reference to FIG. 1 through FIG. 24B).

The system 2500 may include a controller 2504 operatively coupled to the memory 2502. The system 2500 may also include another electronic apparatus 2506 and one or more peripheral device(s) 2508. The other electronic apparatus 2506 may, in some embodiments, include one or more of microelectronic device structures (e.g., the microelectronic device structure 1200 of FIG. 12A and FIG. 12B, the microelectronic device structure 1700 of FIG. 17A and FIG. 17B, the microelectronic device structure 1800 of FIG. 18A and FIG. 18B, the microelectronic device structure 1900 of FIG. 19A and FIG. 19B, the microelectronic device structure 2000 of FIG. 20A and FIG. 20B, and/or the microelectronic device structure 2400 of FIG. 24A and FIG. 24B, respectively), according to embodiments of the disclosure and fabricated according to one or more of the methods described above. One or more of the controller 2504, the memory 2502, the other electronic apparatus 2506, and the peripheral device(s) 2508 may be in the form of one or more integrated circuits (ICs).

A bus 2510 provides electrical conductivity and operable communication between and/or among various components of the system 2500. The bus 2510 may include an address bus, a data bus, and a control bus, each independently configured. Alternatively, the bus 2510 may use conductive lines for providing one or more of address, data, or control, the use of which may be regulated by the controller 2504. The controller 2504 may be in the form of one or more processors.

The other electronic apparatus 2506 may include additional memory (e.g., with one or more microelectronic device structures (e.g., the microelectronic device structure 1200 of FIG. 12A and FIG. 12B, the microelectronic device structure 1700 of FIG. 17A and FIG. 17B, the microelectronic device structure 1800 of FIG. 18A and FIG. 18B, the microelectronic device structure 1900 of FIG. 19A and FIG. 19B, the microelectronic device structure 2000 of FIG. 20A and FIG. 20B, and/or the microelectronic device structure 2400 of FIG. 24A and FIG. 24B, respectively)), according to embodiments of the disclosure and fabricated according to one or more of the methods described above. Other memory structures of the memory 2502 and/or the other electronic apparatus 2506 may be configured in an architecture other than 3D NAND, such as dynamic random access memory (DRAM), static random access memory (SRAM), synchronous dynamic random access memory (SDRAM), synchronous graphics random access memory (SGRAM), double data rate dynamic ram (DDR), double data rate SDRAM, and/or magnetic-based memory (e.g., spin-transfer torque magnetic RAM (STT-MRAM)).

The peripheral device(s) 2508 may include displays, imaging devices, printing devices, wireless devices, additional storage memory, and/or control devices that may operate in conjunction with the controller 2504.

The system 2500 may include, for example, fiber optics systems or devices, electro-optic systems or devices, optical systems or devices, imaging systems or devices, and information handling systems or devices (e.g., wireless systems or devices, telecommunication systems or devices, and computers).

Accordingly, disclosed is an electronic system comprising at least one microelectronic device including one or more of the microelectronic device structures described above (e.g., the microelectronic device structure 1200 of FIG. 12A and FIG. 12B, the microelectronic device structure 1700 of FIG. 17A and FIG. 17B, the microelectronic device structure 1800 of FIG. 18A and FIG. 18B, the microelectronic device structure 1900 of FIG. 19A and FIG. 19B, the microelectronic device structure 2000 of FIG. 20A and FIG. 20B, and/or the microelectronic device structure 2400 of FIG. 24A and FIG. 24B, respectively). The at least one microelectronic device is in electrical communication with at least one processor and/or with at least one peripheral device.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents.

What is claimed is:

1. A microelectronic device, comprising:
a stack structure divided into blocks and comprising a vertically repeated sequence of tiers respectively comprising:
at least one level with an insulative structure; and
at least one other level with a conductive structure and with at least one non-conductive structure;
an array of pillars extending substantially vertically through a height of the stack structure in a first area of the stack structure in which the tiers comprise the insulative structures and the conductive structures and do not comprise the non-conductive structures; and
conductive contacts extending substantially vertically to various depths of the stack structure in a second area of the stack structure horizontally adjacent the first area, in which second area the tiers comprise the insulative structures and both the conductive structures and the non-conductive structures.

2. The microelectronic device of claim 1, wherein the non-conductive structures are horizontally between neighboring conductive contacts in a respective one of the blocks.

3. The microelectronic device of claim 1, wherein, in each of the levels with the conductive structure and with the at least one non-conductive structure, the conductive structure is substantially continuous along a width of the block.

4. The microelectronic device of claim 1, wherein the conductive contacts respectively comprise an expanded base.

5. The microelectronic device of claim 4, wherein:
the conductive structures of the stack structure extend horizontally into the expanded bases of the conductive contacts; and
conductive material of the conductive contacts extends to an upper surface of the conductive structures proximate the expanded bases of the conductive contacts.

6. The microelectronic device of claim 4, wherein:
the conductive structures of the stack structure do not extend into the expanded bases of the conductive contacts; and
conductive material of the conductive contacts fills the expanded bases of the conductive contacts and abuts the conductive structures along a sidewall of the expanded bases.

7. The microelectronic device of claim 1, further comprising, in the second area of the stack structure, supports extending substantially vertically through the height of the stack structure.

8. The microelectronic device of claim 7, wherein the supports are not disposed horizontally between the conductive contacts of respective ones of the blocks.

9. The microelectronic device of claim 1, further comprising at least one inter-block structure comprising a non-conductive material and disposed proximate at least one side of a respective one of the blocks.

10. The microelectronic device of claim 9, wherein the conductive structures of the stack structure extend substantially horizontally toward a middle of the respective one of the blocks.

11. The microelectronic device of claim 9, further comprising an additional inter-block structure comprising the non-conductive material and disposed proximate an additional side of the respective one of the blocks.

12. The microelectronic device of claim 9, further comprising an intra-block structure comprising the non-conductive material and disposed proximate a middle of the respective one of the blocks.

13. The microelectronic device of claim 9, wherein only a single inter-block structure is disposed proximate only a single side of the respective one of the blocks.

14. A microelectronic device, comprising:
a pillar array comprising pillars extending substantially vertically through a stack structure in an array area;
conductive contacts extending various heights through the stack structure in a contact area horizontally adjacent the array area;
in the array area, the stack structure comprising a vertically repeated tier sequence respectively comprising at least one insulative structure and at least one conductive structure; and
in the contact area, the stack structure comprising:
to at least one horizontal side of a respective one of the conductive contacts, the vertically repeated tier sequence respectively comprising the at least one insulative structure and the at least one conductive structure; and
in levels of the stack structure below the respective one of the conductive contacts, an additional vertically repeated tier sequence respectively comprising the at least one insulative structure and at least one non-conductive structure.

15. A method of forming a microelectronic device, the method comprising:
forming a precursor stack comprising a vertically repeated sequence of tiers respectively comprising an insulative structure and a partially sacrificial structure;
forming an array of pillars extending substantially vertically through a height of the precursor stack in an array area of the stack;
forming contact openings extending to various depths of the precursor stack in an additional area of the stack horizontally adjacent the array area;
in the array area of the stack:
substantially wholly removing the partially sacrificial structures to form voids between the insulative structures; and
forming conductive structures in the voids;
in the additional area of the stack:
partially removing the partially sacrificial structures to form additional voids, at least some of the additional voids communicating with the contact openings at respective bases of the contact openings; and
forming additional conductive structures in the additional voids; and
forming conductive contacts in the contact openings and in physical contact with the additional conductive structures at the respective bases of the contact openings.

16. The method of claim 15, wherein substantially wholly removing the partially sacrificial structures precedes partially removing the partially sacrificial structures.

17. The method of claim 15, wherein forming the conductive structures in the voids and forming the additional conductive structures in the additional voids precedes forming the conductive contacts in the contact openings.

18. The method of claim 15, wherein forming the conductive contacts in the contact openings precedes substantially wholly removing the partially sacrificial structures and partially removing the partially sacrificial structures.

19. The method of claim 15, further comprising, before forming the conductive contacts in the contact openings, expanding the respective bases of the contact openings.

20. The method of claim 15, further comprising, before substantially wholly removing the partially sacrificial structures in the array area and before partially removing the partially sacrificial structures in the additional area of the stack:
forming a liner in the contact opening;
removing a base portion of the liner adjacent the base of the contact opening; and
before substantially wholly removing the partially sacrificial structures in the array area partially removing the partially sacrificial structures in the additional area, either:
forming a sacrificial plug to enclose the contact opening; or
forming the conductive contacts in the contact opening.
